(19) United States
(12) Patent Application Publication
(10) Pub. No.: US 2025/0013228 A1
(43) Pub. Date: Jan. 9, 2025

(54) MODULAR, VARIABLE TIME-STEP SIMULATOR FOR USE IN PROCESS SIMULATION, EVALUATION, ADAPTION AND/OR CONTROL

(71) Applicant: Leonard KÅBERG JOHARD, Kazan (RU)

(72) Inventor: Leonard KÅBERG JOHARD, Kazan (RU)

(21) Appl. No.: 18/712,206

(22) PCT Filed: Dec. 6, 2022
(86) PCT No.: PCT/SE2022/051148

§ 371 Date: May 21, 2024

(30) Foreign Application Priority Data
Dec. 10, 2021 (SE) 2151510-1

(51) Int. Cl. G05B 19/418

(52) U.S. Cl. CPC G05B 19/41885

(57) ABSTRACT

A system (20) includes one or more processors (110) and associated memory (120) configured for at least partly operating as a modular simulator having different simulator components. Those components include a first type of simulator component including one or more function approximators, and a second, different type of simulator component configured for interaction with the one or more function approximators. The modular simulator is configured by the one or more processors (110) to operate as a variable time-step simulator based on a variable time-step; and to simulate a dynamic physical process over time based on the first type of simulator component including one or more function approximators and the second, different type of simulator component both given an input based at least in part on the variable time-step.

### TECHNICAL FIELD

The invention generally relates to industrial and/or technical processes and/or other physical processes, and more specifically simulation, evaluation, adaptation and/or control of such processes. In particular, the invention concerns the technical field of industrial/technical simulation and modelling and/or model/control parameter optimization as well as process control.

### BACKGROUND

Industrial and/or technical process control normally involves collecting technical data from sensors coupled to an industrial and/or technical system, refining this technical data into some technical knowledge (modeling) and using the knowledge to produce control signals that create an efficient operation of the industrial and/or technical process.

For these purposes most industries employ some kind of modelling software that assist them in creating knowledge models that can interact with their data. These models are generally encoded in an industry-specific object-oriented modelling language. In some cases, the models are based on physical equations derived from theory, in other cases the models are based on statistical methods such as regression analysis, and in yet other cases the model is based on evolutionary algorithms that may be used for solving both constrained and unconstrained optimization problems based on a natural selection process that mimics biological evolution.

Simulation of such systems typically benefit from variable-step simulations, most commonly based on differential equations solvers, in order to more efficiently handle the simulations. Variable step sizes allow effective simulation of dynamic processes wherein certain critical moments in the process benefits from a smaller step size with higher accuracy, whereas other simulated moments can user faster, larger time steps.

Deriving exact equations for such processes and automatic modelling using universal function approximators, such as neural networks, has been explored in various studies. Recent examples include the pure neural network approach of neural Ordinary Differential Equation systems (Neural ODEs) and the hybrid Physics-Informed Neural Networks (PINNs) that mix neural network and physical equations. These methods place neural networks directly inside differential equations that are fed to differential equations solvers in order to derive a data-adapted simulation of various processes.

However, achieving practical usage of neural networks interacting with differential equation solvers to simulate complex processes requires solutions to several unsolved problems, prohibiting the widespread use of function approximators in such simulators. The perhaps most critical problem is the handling of stiff equations. Stiff equations are variously defined as equations for which certain step-based methods fail without extremely small step sizes, or as equations with patterns acting on different scale or through stiffness ratios. In these settings neural ODEs are known to fail extensively, while e.g. continuous time reservoir computing has worse computational scaling properties and cannot be made to interact with other systems. Furthermore, there is always a need for more efficient computation in order to reduce costs and/or to handler large and/or more detailed models with a higher simulation accuracy.

### SUMMARY

It is a general object to provide improved simulation, evaluation and/or adaptation of model(s) of physical processes such as industrial, technical and/or biomedical or medical processes.

By way of example, it may be desirable to provide more accurate and efficient computer-aided methods for application to industrial and/or technical process models and to use these to create improved control of industrial and/or technical processes.

It is a specific object to provide computationally more efficient simulations that involve universal function approximators trained on data.

It is another object to make efficient automized collection, reuse and manipulation of knowledge implicitly encoded in universal function approximators for use in analyzing and/or controlling physical processes such as industrial, technical and/or biomedical or medical processes.

It is another object to adapt and/or optimize modelling systems that allow an efficient interaction between human understanding of processes and universal function approximation models.

It is yet another object to provide computationally efficient use of sensor data to provide optimal parameterized control systems and/or policies through human-interpretable semi-supervised reinforcement learning.

It is yet another object to provide data-efficient and computationally efficient reinforcement learning-based optimization of control of industrial and/or technical processes through the use of semi-supervised learning.

It is yet another object to provide efficient control of industrial and/or technical processes.

It may also be desirable to provide a method and corresponding systems for enabling simulation of stiff systems using neural networks adapted to data.

These and other objects are met by embodiments as defined herein.

According to a first aspect, there is provided a system comprising:
one or more processors and associated memory configured for at least partly operating as a modular simulator having different simulator components, including:
   a first type of simulator component including one or more function approximators, and
   a second, different type of simulator component configured for interaction with said one or more function approximators;
wherein the modular simulator is configured to, by said one or more processors, operate as a variable time-step simulator based on a variable time-step; and
wherein the modular simulator is further configured to, by said one or more processors, simulate a dynamic physical process over time based on the first type of simulator component including one or more function approximators and the second, different type of simulator component both given an input based at least in part on the variable time-step.

According to a second aspect, there is provided a system comprising:
one or more processors;
a memory configured to store: parameters of one or more universal function approximators;
a variable time-step simulator configured to, by one or more processors, simulate a dynamic physical process over time based on said one or more function approximators given an input based at least in part on a variable time-step and generate a simulation result such that:
each function approximator is based at least in part on a variable time-step
each function approximator is interacting with some simulated dynamic system that is not being simulated by that particular function approximator in the simulator.

According to a third aspect, there is provided a system for evaluating and/or adapting at least one technical model related to a physical process defined as an industrial and/or technical process to be performed by an industrial and/or technical system, wherein said system for evaluating and/or adapting at least one technical model comprises a system according to the first aspect or the second aspect.

According to a fourth aspect, there is provided a system for enabling control of an industrial and/or technical system that is configured for performing a physical process defined as an industrial and/or technical process, wherein said system for enabling control of an industrial and/or technical system comprises a system according to the first aspect or the second aspect.

According to a fifth aspect, there is provided a computer-implemented method for performing a simulation of a dynamic physical process over time. The method comprises:
configuring and/or operating a modular simulator having different simulator components, including:
   a first type of simulator component including one or more function approximators, and
   a second, different type of simulator component configured for interaction with said one or more function approximators;
wherein the modular simulator is configured to operate as a variable time-step simulator based on a variable time-step; and
the modular simulator performing the simulation of a dynamic physical process over time based on the first type of simulator component including one or more function approximators and the second, different type of simulator component both given an input based at least in part on said variable time-step.

According to a sixth aspect, there is provided a method, performed by one or more processors, for evaluating and/or adapting at least one technical model related to a physical process defined as an industrial and/or technical process to be performed by an industrial and/or technical system, said method for evaluating and/or adapting at least one technical model comprising a computer-implemented method for performing a simulation of a dynamic physical process according to the fifth aspect.

According to a seventh aspect, there is provided a method for enabling control of an industrial and/or technical system that is configured for performing a physical process defined as an industrial and/or technical process, said method for enabling control of an industrial and/or technical system comprising a method for evaluating and/or adapting at least one technical model related to a physical process according to the sixth aspect.

According to an eighth aspect, there is provided a computer program comprising instructions, which when executed by at least one processor, cause the at least one processor to perform the method according to the fifth aspect, the sixth aspect or the seventh aspect.

In this way, there are provided methods and systems that enable simulation, evaluation, adaptation and/or control of physical processes such as industrial, technical and/or biomedical or medical processes in a more robust and/or computationally efficient manner.

The invention is normally applicable to any kind of industrial, technical and/or biomedical or medical or possibly even biological processes, examples of which will be described in the detailed description.

By way of example, the proposed technology provides and/or enables the following technical effects:
Automatic design of technical systems.
Control of technical systems.
Automatic design/creation of control systems for technical systems.
Improved technical simulations.
Drug discovery

Other technical advantages provided by the invention may, for example, include one or more of the following: a higher degree of automation, improved computational efficiency, reduced memory requirements, increased control stability, enabling adaptation to stiff systems, provide a way to vary the time step in simulations, enabling training of surrogate models to stiff simulators, faster training of simulators based on function approximators, improved simulator accuracy, enabling larger, more detailed simulation and/or longer simulations given a fixed computational resource, designs of more efficient circuits and/or circuits with reduced size, energy efficiency, faster vehicles, more controllable vehicles, automated control, improved production planning, more accurate motor control, reduced side effects and more effective treatment.

Other advantages offered by the invention will be appreciated when reading the below description of embodiments of the invention.

### BRIEF DESCRIPTION OF THE DRAWINGS

The invention, together with further objects and advantages thereof, may best be understood by making reference to the following description taken together with the accompanying drawings, in which:

FIG. 1 is a schematic diagram illustrating an example of a physical system/process and a corresponding model.

FIG. 2 is a schematic diagram illustrating an example of an industrial and/or technical system for performing a physical process, here defined as an industrial and/or technical process, and a corresponding model of the industrial and/or technical process.

FIG. 3 is a schematic diagram illustrating an example of a biomedical, medical and/or biological process and a corresponding model.

FIG. 4 is a schematic diagram illustrating an example of a simplified system for simulating a dynamic physical system/process over time.

FIG. 5 is a schematic diagram illustrating an example of a system including at least a modular, variable time-step simulator according to an embodiment.

FIG. 6 is a schematic diagram illustrating an example of a system for simulating and/or evaluating at least one technical model related to an industrial and/or technical process, which is performed by an industrial and/or technical system.

FIG. 7 is a schematic diagram illustrating an example of a system for evaluating and/or adapting at least one technical model related to an industrial and/or technical process, which is performed by an industrial and/or technical system

FIG. 8 is a schematic diagram illustrating an example of training a surrogate model by simulating a surrogate model and defining a loss function describing the difference between the models.

FIG. 9 is a schematic diagram illustrating an example of training on historical data.

FIG. 10 is a schematic diagram illustrating an example of interaction between the function approximator(s) and one or more other model(s) or sub-model(s).

FIG. 11 is a schematic diagram illustrating an example of a pulp mill facility, or at least relevant parts thereof.

FIG. 12 is a schematic diagram illustrating an example of a model of pump station operation according to an embodiment.

FIG. 13 is a schematic diagram illustrating an example of a pump or pumping station model.

FIG. 14 is a schematic diagram illustrating an example of a modeling and simulation scheme used for a steerable rocket.

FIG. 15 is a schematic diagram illustrating an example of a pharmacokinetic model.

FIG. 16 is a schematic diagram illustrating an example of a computer-implementation according to an embodiment.

### DETAILED DESCRIPTION

Throughout the drawings, the same reference numbers are used for similar or corresponding elements.

As mentioned, the proposed technology generally relates to industrial and/or technical processes and/or other physical processes, and more specifically simulation, evaluation, adaptation and/or control of such processes.

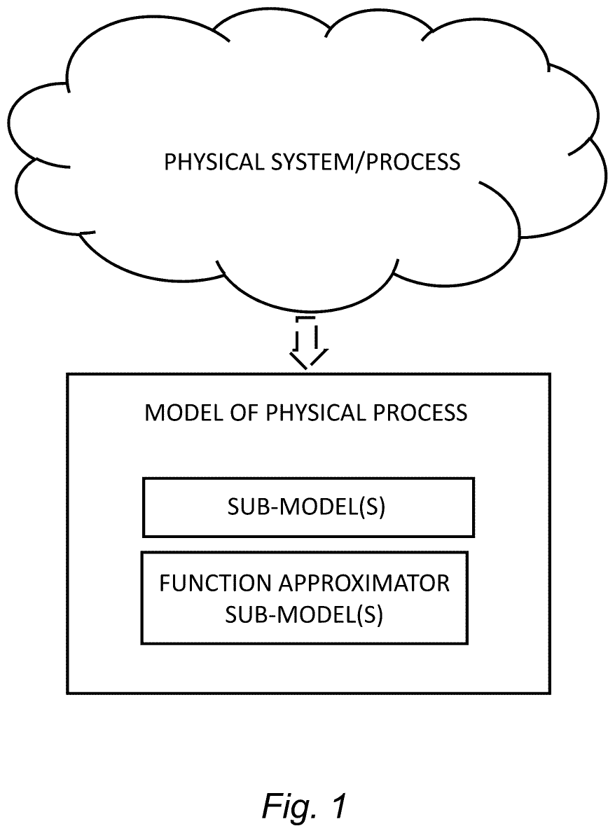

FIG. 1 is a schematic diagram illustrating an example of a physical system/process and a corresponding model of such a physical process. The model may involve various sub-models, including one or more function approximator sub-models.

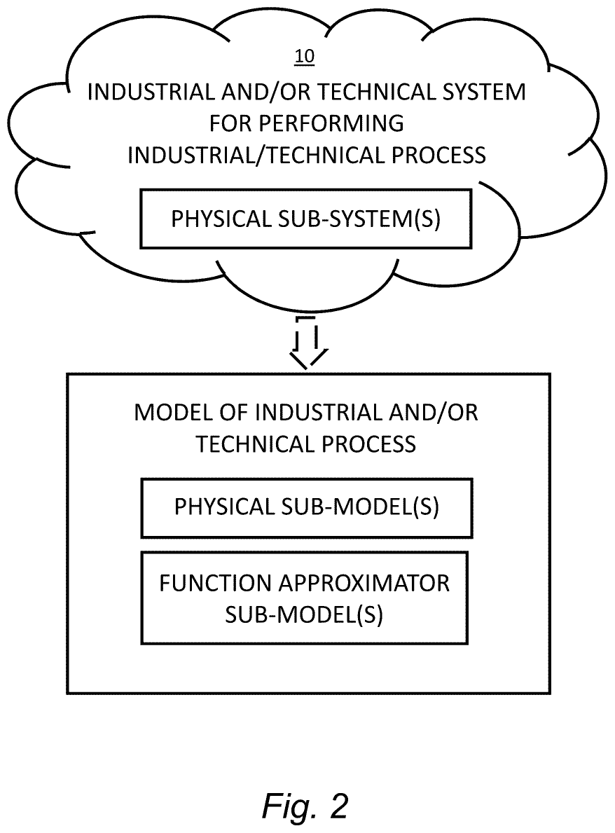

FIG. 2 is a schematic diagram illustrating an example of an industrial and/or technical system 10 for performing a physical process, here defined as an industrial and/or technical process, and a corresponding model of the industrial and/or technical process. The industrial and/or technical system 10 may include one or more physical sub-systems. The model of the an industrial and/or technical process may involve various sub-models, including one or more function approximator sub-models.

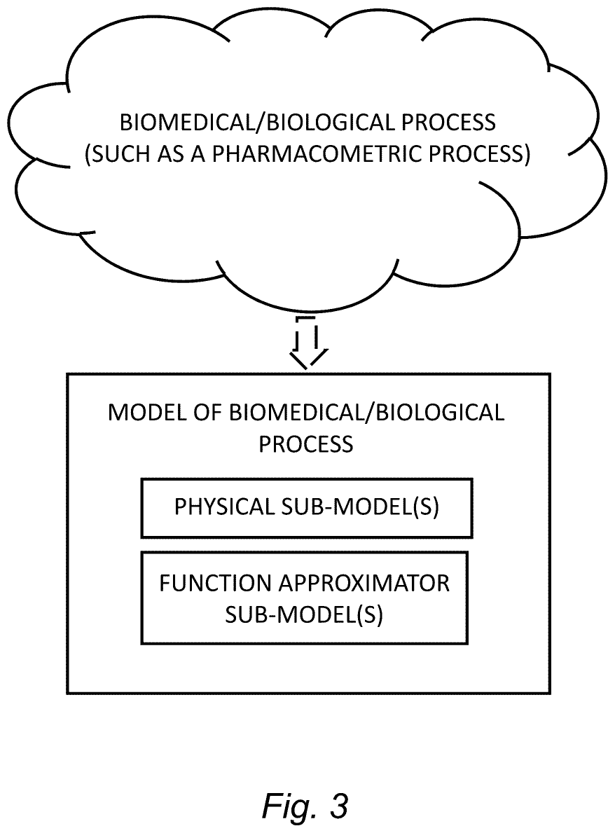

FIG. 3 is a schematic diagram illustrating an example of a biomedical, medical and/or biological process and a corresponding model. The model of the biomedical, medical and/or biological process, such as or relating to a pharmacometric process, may involve various sub-models, including one or more function approximator sub-models.

In the examples of FIG. 1 to FIG. 3, the function approximators may be, e.g. artificial neural network sub-models used as universal function approximators for at least partly modeling the processes.

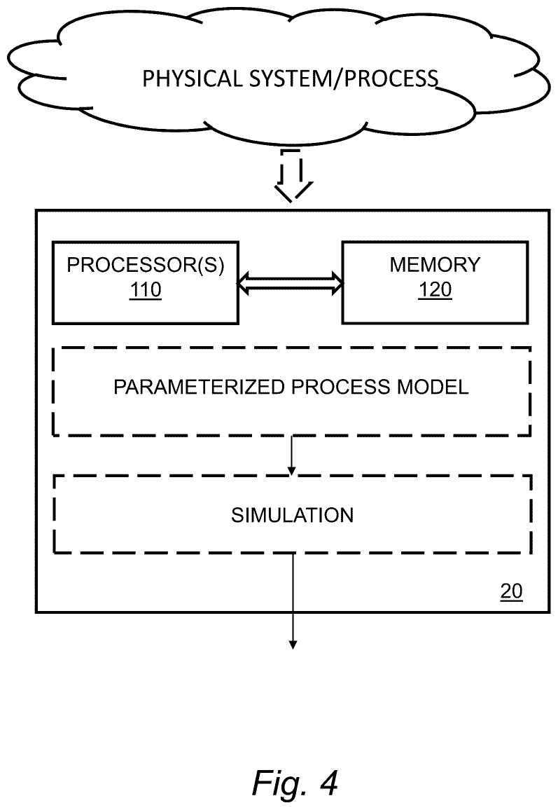

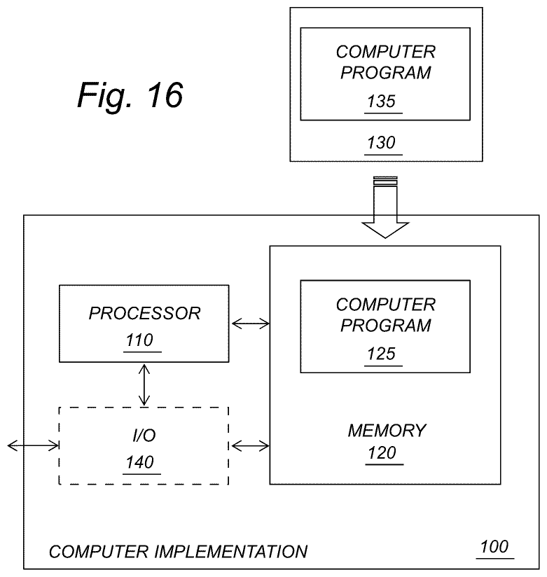

FIG. 4 is a schematic diagram illustrating an example of a simplified system 20 for simulating a dynamic physical system/process over time. By way of example, the system 20 is a processor-memory-based system, in which one or more processors 110 and memory 120 are configured for interaction and operation (see also FIG. 16). Basically, the processor(s) 110 and associated memory 120 are configured for defining and/or maintaining and/or updating a parameterized process model of the physical process and for performing a simulation based on the parameterized process model.

The parameterized process model may be applied to modeling of one or more physical processes or sub-processes, and may also involve modeling of a control process.

The inventor has realized that a modular approach to simulation, with different types of simulator modules or components interacting with each other, may be very beneficial, especially if the simulator is configured to operate based on a variable time-step, and at least a first type of simulator module or component including one or more function approximators has access to information regarding the variable time-step as input. Preferably, the first type of simulator component including one or more function approximators and a second, different type of simulator component are both given an input based at least in part on the variable time-step.

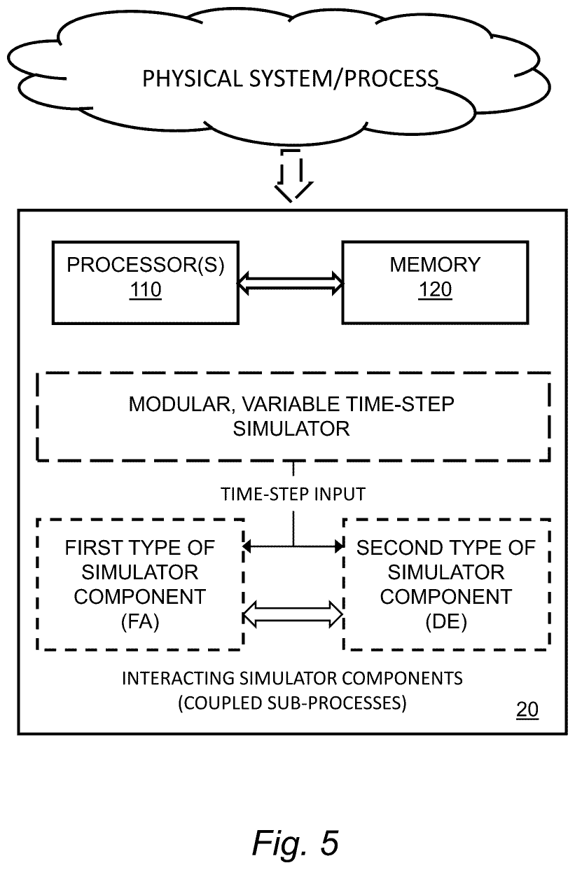

FIG. 5 is a schematic diagram illustrating an example of a system 20 including at least a modular, variable time-step simulator according to an embodiment.

According to a first aspect, there is provided a system 20 comprising:
one or more processors 110 and associated memory 120 configured for at least partly operating as a modular simulator having different simulator components, including:
   a first type of simulator component including one or more function approximators, and
   a second, different type of simulator component configured for interaction with said one or more function approximators.

By way of example, the modular simulator is configured to, by said one or more processors 110, operate as a variable time-step simulator based on a variable time-step. The modular simulator is further configured to, by said one or more processors 110, simulate a dynamic physical process over time based on the first type of simulator component including one or more function approximators and the second, different type of simulator component both given an input based at least in part on the variable time-step.

For example, the interaction between the first type of simulator component including one or more function approximators and the second, different type of simulator component is such that both influence the operation of the other.

In a particular example, the second, different type of simulator component includes one or more differential equation solvers operable with variable step size.

Preferably, each function approximator is based at least in part on a variable time-step, and each function approximator is interacting with some simulated dynamic system that is not being simulated by that particular function approximator in the modular simulator.

According to a second aspect, there is provided a system 20 comprising:
one or more processors 110;
a memory 120 configured to store: parameters of one or more universal function approximators;
a variable time-step simulator configured to, by one or more processors 110, simulate a dynamic physical process over time based on said one or more function approximators given an input based at least in part on a variable time-step and generate a simulation result such that:
each function approximator is based at least in part on a variable time-step
each function approximator is interacting with some simulated dynamic system that is not being simulated by that particular function approximator in the simulator.

By way of example, the dynamic physical process is an industrial, technical and/or biomedical or medical process. Various examples of such process are outlined herein.

In a particular example, the system described herein and above further comprises an adaptation module configured to, by the one or more processors 110) to update at least one model parameter of a parameterized model of the physical process based on an iterative optimization method.

Optionally, the system further comprises a gradient estimator configured to, by the one or more processors 110, estimate a gradient, e.g. on a loss function with respect to parameters of said one or more function approximators in order to generate a gradient estimate with respect to said function approximator parameters. The adaptation module may then be configured to receive the gradient estimate and the optimization method may be a gradient-based optimization method.

For example, the memory 120 may be configured to store computer instructions for the loss function such that the loss function can generate, by the one or more processors, an estimate of the difference between the simulation result and historical data.

In a particular example, the gradient estimator is configured to apply reverse-mode automatic differentiation on the loss function in order to generate the gradient estimate.

As an example, at least part of a system state not being updated directly by a parameterized model is simulated by a differential equation solver with variable step size.

Optionally, the function and/or usage of said one or more function approximators is encoded in an acausal modelling language.

By way of example, said one or more function approximators include one or more Universal Function Approximators, UFA.

In particular, said one or more function approximators may include one or more neural networks.

In a particular example, the system described herein and above further comprises a loss module configured to, by the one or more processors, retrieve a simulation result and historical sensor data from the physical process and generate a simulator loss.

Optionally, the system described herein and above further comprises a control optimizer configured to, by the one or more processors 110, generate a control plan based on the simulation and sensor data for a specified period and/or a control signal and directing said control plan and/or control signal for controlling an industrial and/or technical process.

By way of example, the system may further include a control optimizer configured to, by the one or more processors 110, generate and/or adjust parameters encoding the behaviour of a control system of an industrial and/or technical process.

Optionally, the memory 120 is configured to store: a parameterized model of said physical process, comprising at least one physical sub-model and at least one neural network sub-model used as a universal function approximator for at least partly modelling the physical process, including one or more model parameters of the parameterized model, and sensor data including one or more time series parameters originating from one or more data monitoring systems. For example, the modular simulator may be configured to, by one or more processors 110, simulate the dynamics of one or more states of the physical process over time based on the parameterized model and a corresponding system of differential equations.

As an example, the parameterized model may be a fully or partially acausal modular parameterized process model.

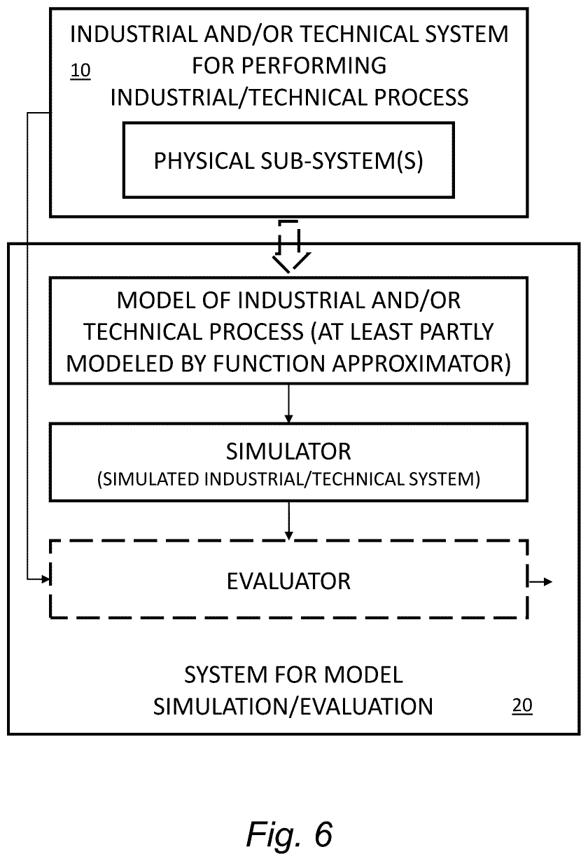

FIG. 6 is a schematic diagram illustrating an example of a system for simulating and/or evaluating at least one technical model related to an industrial and/or technical process, which is performed by an industrial and/or technical system 10.

In the particular example of FIG. 6, the system 20 includes memory for defining or maintaining a model of the industrial and/or technical process (at least partly modeled by one or more function approximators).

The system 20 also includes a simulator configured to, by one or more processors, simulate the industrial and/or technical process or system based on the defined model, and optionally also an evaluator configured to, by one or more processors, generate an evaluation estimate representing an evaluation of the model of the industrial and/or technical process.

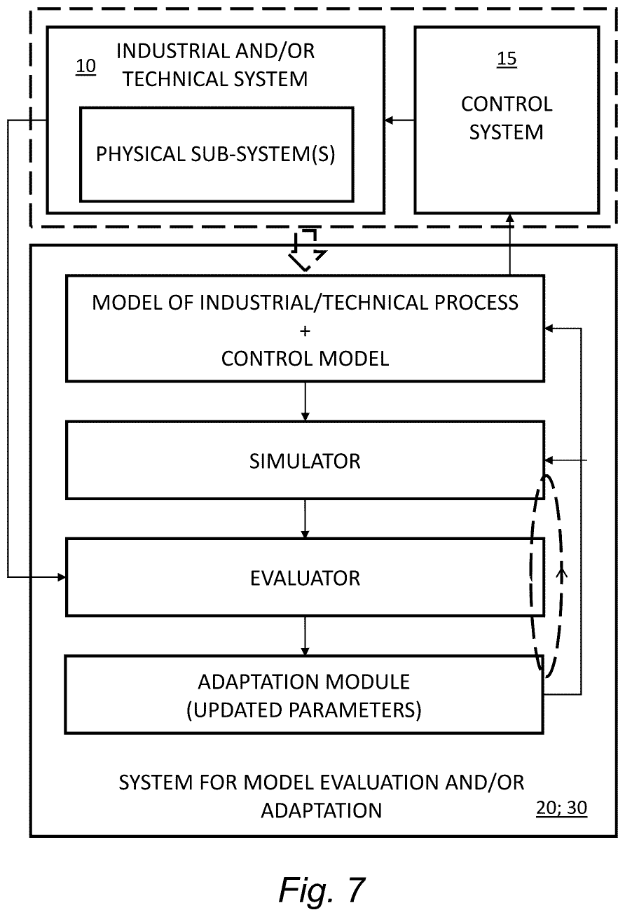

FIG. 7 is a schematic diagram illustrating an example of a system for evaluating and/or adapting at least one technical model related to an industrial and/or technical process, which is performed by an industrial and/or technical system 10.

Basically, the system 20; 30 includes memory for defining or maintaining a model of the industrial and/or technical process and optionally also a control model.

The system 20; 30 further includes a simulator configured to, by one or more processors, simulate the industrial and/or technical process or system based on the defined model, and an evaluator configured to, by one or more processors, generate an evaluation estimate representing an evaluation of the model of the industrial and/or technical process and optionally also an adaptation module configured to, by one or more processors, receive the evaluation estimate to update at least one model parameter of the model of the industrial and/or technical process.

By way of example, the adaptation may be performed by using a gradient-based procedure.

In the particular example of FIG. 7, the industrial and/or technical system 10 is connected to a control system 15 configured for controlling at least part of the industrial and/or technical system 10.

For example, the model of the industrial and/or technical process may be combined or integrated with a control model corresponding to a parameterized version of the control system 15. The overall integrated model is then used as a basis for simulating the industrial and/or technical process including the operation of the control system 15 on the industrial and/or technical system 10, and the integrated model is evaluated and adapted, in a similar manner as previously described. In this way, it is possible to evaluate and/or adapt the integrated model, providing the possibility to update one or more parameters of both the parameterized process model and the parameterized control model, thereby allowing improved control of the industrial and/or technical process.

According to a third aspect, there is thus provided a system 20; 30 for evaluating and/or adapting at least one technical model related to a physical process defined as an industrial and/or technical process to be performed by the industrial and/or technical system 10, wherein said system 20; 30 for evaluating and/or adapting at least one technical model comprises a system according to the first aspect or the second aspect.

By way of example, the system 20; 30 may be configured to obtain the technical model(s), including one or more model parameters. For example, the model may be defined such that the industrial and/or technical process is at least partly modeled by one or more neural networks used as (universal) function approximator(s).

Further, the system 20; 30 may be configured to obtain technical sensor data representing one or more states of the industrial and/or technical process at one or more time instances.

For example, the system 20; 30 may be configured to simulate the dynamics of one or more states of the industrial and/or technical process over time based on the model and a corresponding system of differential equations.

In a particular example, the system 20; 30 is configured to apply automatic differentiation with respect to the system of differential equations and generate an estimate representing an evaluation of the parameterized process model of the industrial and/or technical process, and the system 20; 30 may be configured to generate the evaluation estimate at least partly based on the technical sensor data.

Further, the system 20; 30 may be configured to update at least one model parameter of the model of the industrial and/or technical process based on the generated evaluation estimate and based on a gradient-based procedure, and store the new parameters to memory, for use when producing control signals that control the operation of the industrial and/or technical process.

According to a fourth aspect, there is provided a system for enabling control of an industrial and/or technical system that is configured for performing a physical process defined as an industrial and/or technical process, wherein said system for enabling control of an industrial and/or technical system comprises a system according to the first aspect or the second aspect.

In a particular example, the system 20; 30 further comprises an evaluator configured to, by the one or more processors, generate an evaluation estimate representing an evaluation of a parameterized model of the industrial and/or technical process, wherein the evaluator is further configured to generate the evaluation estimate at least partly based on sensor data.

The system 20; 30 may further include an adaptation module configured to, by the one or more processors, receive the evaluation estimate to update at least one parameter of the parameterized model based on a gradient-based procedure, and to direct the updated process model parameter(s) for use when producing control signals that control the operation of the industrial and/or technical process.

In a particular example, the system 20; 30 further comprises, as part of the simulator:
a compiler configured to, by the one or more processors, receive the parameterized process model and create a system of differential equations;
one or more differential equation solvers configured to, by the one or more processors, receive the system of differential equations and simulate the industrial and/or technical process through time.

By way of example, the differential equation solver(s) may be configured to, by the one or more processors, simulate the dynamics of state(s) of the industrial and/or technical process over time, and the evaluator may be configured to, by the one or more processors, generate an estimate of a gradient related to one or more states derived from the differential equation solver(s) with respect to at least one loss function for output to the adaptation module.

For example, the loss function or functions may represent an error of the simulation in modelling the industrial and/or technical process.

According to a fifth aspect, there is provided a computer-implemented method for performing a simulation of a dynamic physical process over time. The method comprises:
configuring and/or operating a modular simulator having different simulator components, including:
   a first type of simulator component including one or more function approximators, and
   a second, different type of simulator component configured for interaction with said one or more function approximators;
wherein the modular simulator is configured to operate as a variable time-step simulator based on a variable time-step; and
the modular simulator performing the simulation of a dynamic physical process over time based on the first type of simulator component including one or more function approximators and the second, different type of simulator component both given an input based at least in part on said variable time-step.

According to a sixth aspect, there is provided a method, performed by one or more processors, for evaluating and/or adapting at least one technical model related to a physical process defined as an industrial and/or technical process to be performed by an industrial and/or technical system, said method for evaluating and/or adapting at least one technical model comprising a computer-implemented method for performing a simulation of a dynamic physical process according to the fifth aspect.

According to a seventh aspect, there is provided a method for enabling control of an industrial and/or technical system that is configured for performing a physical process defined as an industrial and/or technical process, said method for enabling control of an industrial and/or technical system comprising a method for evaluating and/or adapting at least one technical model related to a physical process according to the sixth aspect.

By way of example, the methods described herein may be applied for simulation, adaptive modeling and/or control of at least part of an industrial and/or technical system for at least one of industrial manufacturing, processing, and packaging, automotive and transportation, mining, pulp, infrastructure, energy and power, telecommunication, information technology, audio/video, life science, oil, gas, water treatment, sanitation and aerospace industry.

For a better understanding of the proposed technology, it may be useful to proceed with a more detailed description of particular example implementations as well as illustrative and non-limiting explanations of some useful technical terms.

By way of example, the system may be configured to store parameters of one or more function approximators. The definition of approximator here denotes the flexibility of the method and includes any non-linear approximations that can effectively approximate large classes of non-linear functions with mild constraints, for example non-linear neural networks, non-linear support vector machines and many types of reservoir computers. For example, a function displaying a universal function approximation property is suitable as a function approximator herein, even in case if it is mildly regulated and/or restricted in output. A purely linear model or a specific physics-derived non-linear function with few and hard-coded hyperparameters and whose power cannot easily be adapted to data points by increasing one or more hyperparameters, however, is not a function approximator.

In the preferred embodiment, the system uses a neural network as function approximator, with its corresponding base and weights of each neuron as the parameters of the function approximator. Usually, a single hidden layer with dense connections, a leaky relu activation function and 100 neurons is sufficient to model many processes.

### Variable-Step Simulator

The proposed technology comprises a variable time-step simulator. Such a simulator is able to adapt the about of time simulated in each iteration of the simulation, for example adjust the time step in order to achieve a target accuracy. Such variable time steps are useful in order to achieve high accuracy on critical moments of the simulation by reducing the time steps, while other parts can be simulated in less temporal detail. The by far most common examples of variable step size simulators are differential equation solvers.

The system is configured to simulate an industrial, technical and/or even biomedical or medical process. Industrial and/or technical processes herein are used widely and includes any processes performed by or in an industrial and/or technical system such as factories, mills, water and sanitation systems, heating systems, electrical transmission systems, power plants, mining operations, refineries and various pipelines.

The simulation result is here based on the output of function approximator. In contrast to neural ODEs, the function approximator is also given the time step as an input in the simulation. Consequently, a function approximator is then able to generate not just the instantaneous rate of change of some continuous physical process that it is simulating, but also the average rate of change for the whole time step. Essentially, it would able to directly imitate any definite integral, with mild restrictions, rather than numerically simulate them in several iterations.

In other word, the function approximator can be described as:

f(u(t),dt)

wherein u(t) is some input depending directly or indirectly on the state and dt is the step size to be simulated.

Note that we do not exclude having the function approximator also depend on other inputs, for example other features describing the input function u(t).

For example, when trained to predict future states of some physical process in a differential equations solver, the function approximator may learn the gradient estimate that will help the solver to produce the best approximation for a given time step.

For example, the function approximator may be used to directly update the state rather than being passed through some differential equation solver. In other words:

$$s ( t + dt ) = s ( t ) + f ( s ( t ) , u ( t ) , dt )$$

where dt is the time step, s(t) some state of the simulation directly influenced by the function approximator and u(t) any external input to the function approximator.

Alternatively, it can directly derive the state as s(t+dt)=f(s(t), u(t), dt). This form may be preferable the process is fast or otherwise the expected to change substantially throughout a time step.

In other cases, it might be desirable to implement the function approximator inside some differential equations solver, such as an ODE, DAE and/or PDE solver. In this case the implementation is also straightforward. For example, it can be encoded in the software in a form similar to neural ODEs:

d/dt s(t)=f(u(t),dt)

Enabling such access to the solver time step by functions inside the differential equations might, however, require modification of existing systems. Technically, the above equation is no longer a differential equation, but it can easily be handled by the same differential equation solver frameworks through the use of such modification. Also, a differential equation can be derived from the limit dt→0. In most cases, the equality dt=0 also results in a differential equation.

In other cases, the function approximator may also be used to update the state in other ways depending on the particulars of the situation. Due to the flexibility of function approximator the choice of how to implement the function approximator is commonly performed based on a desire to accelerate training and improve extrapolation by utilizing useful chemical, physics or process knowledge concerning the system being simulated.

As an example of such knowledge could be in a model where the function approximator simulates a pump that is generating a pressure in a pipe system which in turn generates a flow that fills a reservoir. The flow depends on the physical particulars of the pipe system which may be modelled in a physical model through its physical parameters. The pump can then be simulated by a function approximator, but the state change (e.g. the change in water volume in, before and after the pipe) is not dependent on the pump directly, but by the pump-and-pipe system. The reservoir may have a flow-dependent leakage and a variable area with height.

The change could then be described as:

$$s ( t + dt ) = s ( t ) + g ( s , f ( u ( s ( t ) ) , dt ) , dt ) )$$

where g is some submodel using a differential equation solver to simulate the reservoir change as a result of incoming flow and height and u is submodel simulating the pressure resulting from a state-dependent control of the pump.

The function approximator f with variable step size can then, for example, simulate the effective average pressure that generates the correct average flow in the pipe throughout the time step in order to correctly predict the state change across the time step. Note that the pressure that generates in order to generate the best prediction of state change is not necessarily equal to the true average pressure throughout the time step. However, the true average pressure and the pressure that generates the best prediction will, in the absence of modelling losses, converge as time step decreases.

Inclusion of knowledge as described above is usually useful in a model for generating better extrapolation. On the other hand, it is often better to use a simpler implementation, such as directly updating the state from the function approximator, when such knowledge is not known with certainty or costly to derive.

The accuracy of the preferred embodiment is, in the case of a one-dimensional and noise-free state without external inputs, entirely dependent on the accuracy of the function approximation and otherwise independent of the simulation step. For example, a universal function approximator can, for a large class of physical processes, simulate a wide range of time step to any desired accuracy that is limited only on some hyperparameters, e.g. the number of neurons in the neural network, in a single step of the variable time step simulator. In contrast, a differential equation independent of, or with limited dependency on, the variable time step would generally need a smaller step size.

The advantages when extrapolating to new situations can briefly be summarized as follows: The function approximator can also fail in correctly predicting the behaviour over the time step, for example when faced with a change of its input or in how the function approximator is used to update the state. However, in these cases reducing the step size will reduce the necessity to predict input and output for any continuous functions state updates. If the state of the physical system to be simulated is piece-wise continuous, it can be simulated to any numerical accuracy by choosing smaller step sizes. The accuracy on the small scale is only limited by the model accuracy, which approaches zero with sufficient data and hyperparameters such as the number of neurons, and the step size, which approaches zero as we reduce step size.

On larger scales, a model is also limited by its knowledge of its context, which can be provided as additional features to the function approximator. Given sufficient features in the training to describe any context the function approximator will act in, also the large-scale error of a deterministic simulation can be reduced to zero.

In other words, training of the function approximator in the simulator is sound and, given a set of data, its desired behaviour is independent of simulation step size used in a particular simulation.

In contrast, a neural ODE, for example using forward Newton, has no access to the time step of the simulation. As a result, it would ideally produce the average rate-of-change across the time step in order for the integration to reach the desired result at the end of the time step. However, the desired average rate-of-change across the time step depends on the size of the time step. Higher order solver methods, such as the Runge-Kutta family, can only compensate this up to some order n for this dependency and can only do so imperfectly. As a consequence, the desired behaviour of a neural ODE will depend not only on the data, but also on the selection of step sizes of the solver used to simulate it. This will create different desired behaviours from a function approximator as step size changes, which limits accuracy and stability of the training. For example, simulating with a large step size may imply unsuitable behaviour for small step size, and vice versa. The best the model can do in this case is to settle for a compromise between the desired behaviour for the large and the small step size, which is clearly represented by suboptimal parameters for both cases.

### Loss Function

Some aspects of the invention comprise a memory storing a loss function. A loss function commonly refers to a measure (known as “loss”) of the correctness of a model on some historical training data. It can be expressed as a single value that is a function of the model parameters, including the parameters of the function approximator. Common types of loss functions are, for example, the mean squared error and mean absolute error.

The loss function may optionally be stored in the memory, for example as computer instructions or as appropriately encoded symbolic and/or algebraic representations that can be automatically processed and used to generate such instructions. In other cases, the loss function is just used implicitly in designing the gradient estimate.

### Automatic Differentiation

A system for efficiently generating the gradient can be derived by reading computer instructions encoding the loss function and applying a set of computer instructions, through the one or more processor, to the loss function that automatically generate a different set of computer instructions that, when given the parameters, will generate the gradient based on these instructions. If the generation of the loss function is based on automatically applying simple rules to the loss function (e.g. the computer instructions or the encoded algebraic representation of the loss function), this is known as automatic differentiation. Automatic differentiation is usually contrasted to numerical methods, such as finite difference methods, which utilize differences in the loss function when simulated repeatedly with small variations in the input in order to generate the output.

Automatic differentiation divided into two main branches; forward mode and reverse (or adjoint) mode. One central difference is that reverse mode has a forward pass, largely analogous to the original program code but where parts of the intermediate program state needs to be preserved for the backward pass, and a later backward pass where the preserved intermediate program state is used to calculate the derivatives. There is also mixed-mode automatic differentiation, where limited forward mode is used in some calculations within an overall reverse-mode automatic differentiation. Benefits of reverse-mode automatic differentiation is that the gradient computation will be efficient when simultaneously generating gradients for a large amount of parameters.

The preferred embodiment of the invention uses reverse mode or mixed mode automatic differentiation on an encoded loss function stored in memory in order to generate an efficient gradient estimator. For this, the loss function is encoded in one or more computer language(s) suitable to automatic differentiation, for example TorchScript, a Tensorflow graph, Julia and/or suitable subsets of Python and/or C++. Since the loss function is calculated using the variable time step simulator, this simulator should also be encoded in a computer language suitable to automatic differentiation in these particular embodiments of the invention.

### Gradient Estimator

Some aspects of the invention involve a gradient estimator. The gradient estimator is module that reads the parameters from memory and generates the gradient on the loss function. The loss function is can either be stored explicitly on the memory, in which case the gradient estimator can be generated automatically through automatic differentiation, or just encoded implicitly in the configuration of the gradient estimator so that it calculates the gradient of the loss function.

The gradient estimator does not necessarily generate the true gradient on the loss function from the parameters. The gradient estimator may generate stochastic outputs, for example by performing stochastic gradient descent by generating a gradient estimate on a randomly chosen subset of the data points. Similarly, the gradient does not necessarily refer to the regular gradient, but may also use natural gradients, conjugate gradients or other variations. The requirements necessary for effective gradient estimates to be effective can be considered well-known in the field. The gradient estimate should, for example and slightly simplified, on average have a positive inner product with the true gradient.

### Adaptation Module

An adaptation module, sometimes called an optimizer, is a module that reads parameters from memory, receives the gradient estimate from the optimizer and generates updated parameters. The objective of the parameter update is to adjust the parameters so that the variable-step simulator creates better simulation results on historical data, as evaluated by the loss function.

Data adaptation can utilize a variety of iterative optimization methods, for example genetic algorithms and gradient-based methods. Gradient-based methods include, for example, stochastic gradient descent, Nestorovs momentum and second-order methods such as sequential quadratic programming. The gradient-based methods can receive the required gradient estimates from gradient estimators utilizing a variety of methods, for example: the REINFORCE algorithm, finite difference method and automatic differentiation.

Data Adaptation with Variable Step Sizes

In contrast to a neural ODE or similar function approximator that is independent of the differential equation solver step size, our simulation system can learn to simultaneously predict the different time scales of stiff systems and can, consequently, effectively separate the dynamics of small and large time steps. This can break any correlation between simulation step size and desired target gradient for that particular step size. Such correlations may otherwise introduce instabilities when training a neural ODE or corresponding hybrid physics-and-function-approximator hybrid model inside a variable time-step simulation, which prevents convergence.

For example, a small step size in conjunction with training a function approximator without step size will train it to predict the immediate rate of change, while a larger step size will naively train it to predict the average rate of change over that larger time step. The situation can be no more than imperfectly compensated by simulator that try to predict this change, for example using multistep methods in differential equations. In most cases, the parameters that give the best prediction for a simulator across a time step is a continuous function of the time step.

Summarizing, training such a function approximator without time step on different time steps, for example by training it on periods that require small time steps and periods that can rely large time steps in order to achieve a given solver accuracy, will create a moving target for the function approximator that may slow or prevent convergence.

The usage of a function approximator can serve several advantages compared to a physically derived differential equation. It can, like neural ODEs, identify a solution from experimental data when such are unknown. Additionally, it may speed up simulation by allowing larger time steps. This second advantage can be applied even when the precise differential equations are known. For example, a model used in an iteratively improving optimization algorithm might need to run thousands of almost identical simulations. The invention can be used to derive a simulation model that allows larger time step in each iteration, thus speeding up convergence. It can then be worthwhile to spend computation time training a function approximator on simulated solutions to the differential equations in order to be able to use the function approximator in the optimization loop.

### Choosing Step Sizes During Training

A function approximator adapted to data is limited by the quality of the data used to train it. A variable-step simulator may request a smaller time step than was ever used to train the function approximator. In such cases, we are extrapolating into new smaller step sized than observed and there is a high risk of erroneous behaviour that can be prevented in various ways. It may, for example, be beneficial to introduce regularization or to set a minimum step size under which the model simply uses the minimum step size as input and assumes a constant rate of change. For example, we may make a total change of the state that is equivalent to the output of function approximator, when fed the minimum time step, multiplied by the variable time step divided by the minimum time step.

$$s ( t + 1 ) = s ( t ) + {f ( u ( s ) , dt\_min )}^{*} dt / dt\_min$$

As mentioned earlier, when composing a function approximator model together with an externally simulated system, for example another function approximator or parts of a simulation simulated by other methods, the assumption that the modelling error can be zero (or limited by machine precision) is no longer true in the general case. For example, the exact shape of the dynamic input between the time steps, i.e. between t and t+dt, cannot be known by the model without further assumptions. At the same time, and particularly so in complex modular simulation engines, we would like each model to update accurately regardless of what systems are connected to our simulated module, for example to run hypothetical scenarios and/or if we would later like to modify a control system influencing the system. Continuing this example, when adapted to data with variable input, a function approximator will implicitly assume that the input between t and t+dt is similar to the input given during training in similar situations. This will not necessarily be true for all the various use cases of the simulation. For example, it might not be true if we simulate the performance of the system in a new environment. However, if we assume a piece-wise continuous input and an ideal piece-wise continuous function approximator, the error of this implicit assumption gets smaller as we reduce the size of time step dt. In other words, the error in the input assumption arising from errors in predicting inputs will shrink with simulation step size. In other words, smaller time steps will reduce the simulation error when facing new situations. When a module is acting in simulation contexts similar to training data, it can be simulated with larger time steps. When simulating in unfamiliar contexts, a smaller time steps allows higher accuracy, as the need for accurately predicting the context outside of the particular module is reduced with time step.

The same risk is present to a lesser extent during interpolation or while simulating larger step sizes. However, an accurate model for a smaller time step typically allows accurate prediction over longer time scales. For example, several accurate predictions using small time step can be used to produce a training target for a longer time step equivalent to the sum of all such smaller time steps. This can be used to construct regularization criteria and/or used for generating synthetic training data to better handle longer time scales. On the other hand, the system can theoretically be fed any input between the start and end of the larger time step, so a prediction across a larger time step always includes an implicit assumption about the dynamics of any input for the whole time step. Any larger time step will have a potential error contribution due to the input assumptions that grows with the size of the time step. Changing the behaviour of the input may reduce the efficiency of large time steps, while smaller time steps are less affected. This should preferably be automatically detected by the solver, and the time steps consequently automatically reduced when unfamiliar inputs are presented.

Similarly, two smaller time steps can be randomly chosen so that they add up to a larger time step for which data or reliable simulation is available. In this case, the limitation that two consecutive small steps should give the same result as one equivalent large time step with known output allows an infinite number of solutions. This under determination naively gives no guarantee in the general case that such extrapolation to smaller time steps provides the same dynamics as any physical system. This is in particular true for data with fixed time steps. However, a dataset that consists of samples from an effectively random and continuous range of time steps can, with mild assumptions, be trained in this way to any accuracy also for smaller time steps if given enough training samples, as any inconsistency between the physical system and the model on the smaller time scales will generate a loss in the data set that correlates with the time step, which can then be removed from the model with sufficient training.

Training to convergence can in these cases reduce the accuracy to any desired level for any time step, given that the number of sampled data points and the hyperparameters of the function approximator are set appropriately, e.g. given a large enough number of nodes in the neural network. This is true even if there is a smallest time step in the data samples. In many practical situations, a function approximator is also likely to generate a good enough extrapolation to smaller time steps for the purposes of simulation, even if the above described conditions are not met and convergence to a zero error cannot be guaranteed.

Once a function approximator is in a fixed environment, i.e. when consistently fed a particular input, the model error with longer step sizes can be reduced by training the function approximator to predict the state of two or more of its steps in a single longer time steps. The primary source of error of a function approximator trained with large amounts of data is the intra-step variability of its input. Training in a specific environment will take this into account to the extent to which it is predictable from the given inputs.

### Additional Input Features

Inputs can be described in various way. Here the ideal description of the input is one that allows a system to make an accurate prediction based on data and for which sufficient data is available to explain the differences in the historical data and that can, when necessary, be used to extrapolate to any new desired situations. For example, in order to predict the behaviour of a pump, its physical characteristics can be used as predictors in order to implicitly predict its dynamic behaviour, e.g. how fast it is able to increase pressure. In another example, encodings of the specific pumping control system can also be provided. If we instead assume that these are not known in the historical data, we may instead look at other features that describes its dynamics. For example, the derivates up to some order n can be estimated from the data and/or provided by a simulator of such a pump and used to, implicitly, predict the future state in some temporal neighborhood.

Using input features providing such additional information to extend the input allows the step size to be increased with preserved accuracy for a larger range of connected pump simulation. This allows the function approximator to be trained with a range of inputs and use this knowledge to better predict the system state when given an identical input or when extrapolating to a new type of input that is described by the features. The better the features the lower the error due to input uncertainty. For example, features that perfectly describes the input may, with sufficient data and training, converge to either a zero error or, if the system is stochastic, an accurate prediction of the distribution mean. Note that the error caused from erroneous input prediction can, as indicated above, alternatively be reduced by reducing step size, i.e. sampling the input values more often. However, smaller step sizes come at a computational cost, which means that the net effect of an effective feature description is higher simulation speeds on new types of inputs.

Examples of features that are effective in describing the input depends on the corresponding interacting systems. A first order term, i.e. providing the time derivative of the input system as a feature, is often effective. More complex situations

A full description of the input would require a function input, which is an infinite-dimensional variable that is not generally encodable in a fixed number of floating point numbers. The function approximator might also need to extrapolate in the input space to new types of inputs, which means that a low-dimensional representation might be provide denser data points in the feature space and better extrapolation.

Training from Data for Modularity

As mentioned before, the ability to simulate with arbitrarily small time steps is desirable in order to maintain modularity of the simulation, i.e. for the simulation each module to perform well when put in new contexts due to factors external to those simulated by the module.

In the preferred embodiment, when applied to learning an unknown function, the function approximator is trained to predict the state, or the equivalent change of state, from one data sample to the next in a continuous time series. In parallel, a random time is sampled in between the two times of the data samples. The function approximation is then also trained to predict the state of this intermediate time and, subsequently, the next data sample from the state of the intermediate time. In pseudocode, the predictions can be stated as:

pred_1 := f(s_init, dt_tot)
pred_2 := f( f(s_init, dt_1), dt_2)

where f is prediction of the next state, or part of the state, based on the function approximator, s_1 is some initial state sampled from the data samples, d_tot is a the time difference to the next consecutive data sample in the historical data, s_1 is a random intermediate time between 0 and d_tot and s_2 is calculated as dt_tot-dt_1.

We then use the adaptation module to minimize the data sample contribution to the loss function:

$$( pred\_ 1 - s\_ 2 ) \hat{} 2 + ( pred\_ 2 - s\_ 2 ) \hat{} 2$$

where the loss function will be the average of the above value across all data samples. If the state consists of multiple values, the loss function can, for example, be summed over each individual state. The contribution to the loss for each component of the state may also, for example, be weighted according to its importance, variance etc.

Details may differ depending on the technical context. In some situations, the mean squared error above will be replaced by mean absolute error. It may also be relevant to scale the sample contribution by some factor, for example the size of the time step until next sample. Such considerations may, for example, depend on how the data is sampled, robustness to outliers and the estimated cost of mistaken predictions of various magnitudes and frequency.

Note that the loss function above is the contribution from a single sample and that the complete loss function in the preferred embodiment is the sum across a multitude of combinations of: data samples in a data set and sampled intermediate times.

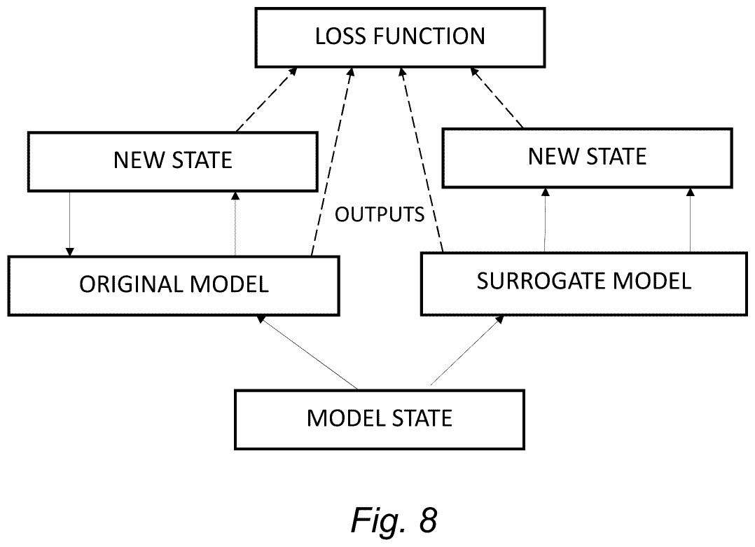

FIG. 8 is a schematic diagram illustrating an example of training a surrogate model by simulating a surrogate model and defining a loss function describing the difference between the models. By way of example, the loss function may depend on outputs and/or states of the simulation.

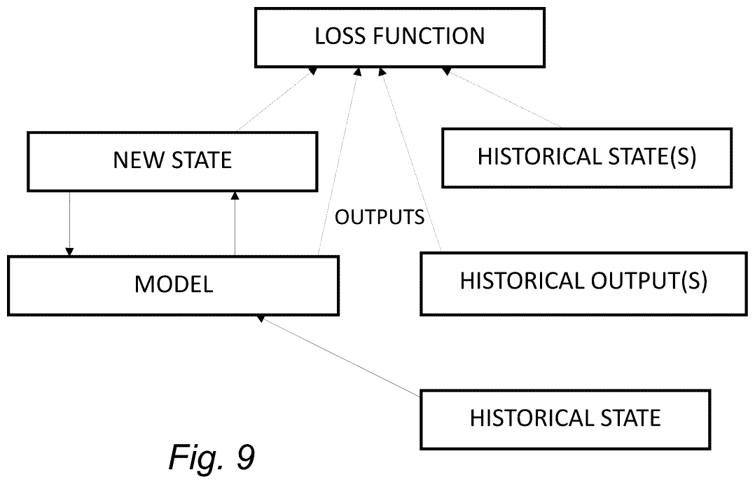

FIG. 9 is a schematic diagram illustrating an example of training on historical data. By way of example, the loss function may describe the difference between the physical system, optionally including parts of its environment, and a model based on some outputs of the model and/or its state compared to its physical equivalents as recorded in the historical data.

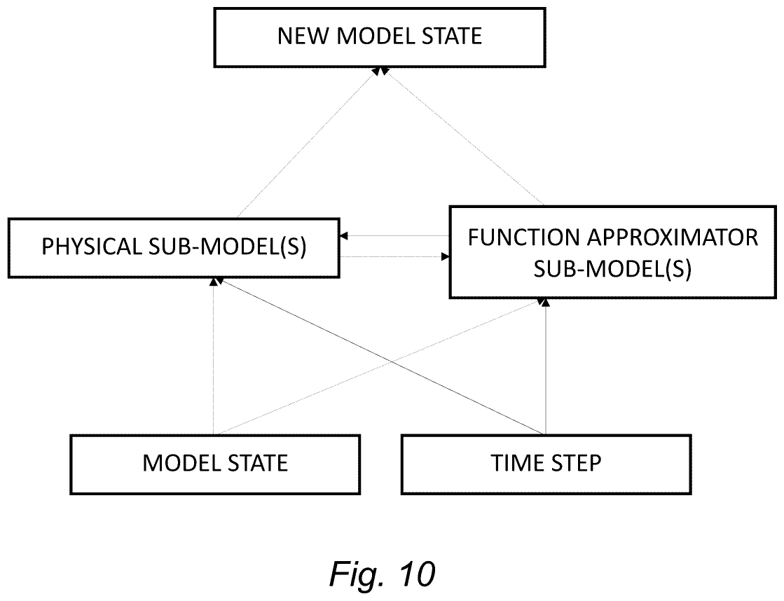

FIG. 10 is a schematic diagram illustrating an example of interaction between the function approximator(s) and one or more other model(s) or sub-model(s), e.g. implemented as individual components in the simulator. By way of example, the interaction between the function approximator and the one or more other model(s) it interacts with can be take many different forms.

By way of example, at least one other model or sub-model may also be dependent on the time step.

The interaction may take different forms depending on the specifics. For example:

The other model or sub-model may depend on some output of the function approximator.

The function approximator may depend on some output of the other model.

The other model may influence a state that in turn influences the function approximator in the same or a following time step.

The function approximator may influence a state that influences the other model in the same or a future time step.

### Training Surrogates

Simulators and/or models imitating some other existing simulator and/or models are known as surrogate models. Accelerating simulation through the use of surrogate models is an essential enabler for further uses in many cases, as computational requirements would otherwise prevent any simulation over the necessary time horizons.

For example, when the invention is applied to imitate a particular simulator f_original, for example a simulator trained according to the method above, in order to accelerate simulation speed, the preferred embodiment of the adaptation process will differ. For example, instead of sampling an intermediate step, the simulator is adapted to predict a random simulated period.

f_new(u(s,dt),dt)

where f_new is the desired accelerated simulator based on a function approximator, s some random real or hypothetical state of the simulated system, dt is some random time period, for example sampled uniformly between 0 and some value t_max that represents the largest simulation time of interest.

The loss function contribution from a sample can then be:

(f_new(u(s,dt),dt)−f_original(u(s,dt),dt)))\hat{ }2

where f_original is the prediction of the simulator being imitated. Note that multiple variations on the loss functions are possible also here, with considerations similar to those for identifying an unknown function.

If, for example, the f only influences a state through some other function g and imitation of this state is desired, another potential sample contribution to the loss function could be loss:=abs(g(f_new(u(s,dt),dt))−g(f_original(u(s,dt),dt), where abs is the absolute value.

Note that the above examples of the preferred embodiments are simplified and do not depend on any interaction with an external simulator except, optionally, where these interact through the state alone. When the simulators interact through the state, s depends in part on the function approximator and in part on some other simulator.

In more complex embodiments, the loss may, for example, be based on a complex model with multiple function approximators and physical differential equations encoded in an acausal programming language such as Modelica or Modia. It may, for example, also use FMI in order to interact with a large variety of external simulator, such as finite element simulators.

Accuracy of such prediction depends, as was previously mentioned, on accurately and implicitly being able to predict behaviour of any connected system not simulated by the simulator. The simulator may be extended as

f_new(u(s,dt),v,dt)

where v is some additional features describing the dynamics of the input u and/or the system g influenced by f. Such features assist the simulator in implicitly predicting the intermediate state and/or input between t and t+dt, as described above. For example, it can describe some physical characteristics of the system that the interacting simulator is simulating and/or it can describe the rate of change of x and/or s as calculated by the interacting simulator. Using features more effective in predicting the intermediate state and/or input will reduce the prediction error and/or allow larger simulated time steps to be simulated with a fixed prediction error.

### Mixed Surrogate and Data Adaptation Training

Alternatively, both training methods, i.e. for the purpose of learning from data and for the purpose of reducing computational requirements, above can be combined in a single training process, for example by training the simulator to randomly sample two data points that are not necessarily consecutive and in this way train the function approximator to predict across several samples in the data. This will allow the system to adapt to predictions both small in time and large in time, thus achieving both accurate simulation agnostic to inputs and computationally efficient single-step predictions across larger time steps. A variety of such system and methods will become obvious to the skilled person after achieving familiarity with the technology.

The function simulator may, for example, interact with a variety of simulation types, for example: systems of differential equations, step-based simulations, event-based simulations, finite-element methods and multi-agent models. Model types may, for example, be combined in any way and these submodels may interact with each other in a larger model.

Note that surrogate models can be used to predict, among other model types, the solutions of simulations of differential algebraic equations (DAEs) across some time period. This allows DAEs to be replaced by a function approximator directly estimating the next state as output, rather than just putting the function approximator inside the existing DAE and solving for next state iteratively. This greatly reduced the number of calculations required to calculate a given time step.

Using Dynamic Time Steps with Function Approximators

It is common in variable-step simulations to dynamically change the variable step size throughout the simulation in order to maintain a target accuracy. When using simulating systems assumed to follow a specific systems of equations, for example, it is common to increase or reduce the time step iteratively until the error corresponds to the target estimate. Such estimation of the accuracy is often performed by making two predictions and comparing their values, for example by predicting forward from a state at a certain moment and then backward in time from the predicted future state. The accuracy in this example can be estimated as the difference between the original state. Usually it is stated as a requirement for absolute accuracy per value encoding the state and an additional requirement for relative accuracy expressed in a ratio or percentage of the value or values encoding the state.

Using the invention, the accuracy of simulation for a time step can similarly be estimated in a variety of ways. Nothing prevents the invention from being applied with negative time steps, although limiting it to time steps forward in time may allow for more effective parameterization. The reversed dynamics may display different properties, especially so in stochastic processes, which would need a more complex and computationally expensive function approximator to learn.

Another approach is to, for example, compare the accuracy between a prediction for a full time step and the corresponding prediction for two smaller time steps each equivalent to half the time step. The accuracy can be based on the difference of these predictions.

The use of function approximators introduce an additional source of error that can be introduced in the above accuracy estimate. A function approximator is just an approximation of the desired true system being simulated and any such simulation has an error component that derives from the difference between the actual system and the approximation. A way to estimate this is to create a separate function approximator that estimates the error of the simulator. This error can be trained to estimate the error in predicting the data points based on time steps, similar to how the simulator is estimated. Such error estimation can, for example, be integrated into the model adaptation, so that adaptation of the function approximator and the separate adaption of the other function approximator used for estimation of the first function approximators accuracy are both updated for each data sample.

The accuracy of the simulation can then be estimated as a combination of the function approximation error and the time step accuracy. However, for the sole purpose of adjusting the step size such more precise accuracy estimation may be unnecessary, as only the time step-dependent component may be of interest.

### Benefits of Variable Step Sizes

A key advantage of variable step sizes is that it allows the simulated system to be effectively combined in a modular fashion with other simulated systems in a combined simulator. The dynamic step size can be reduced in order to achieve a required accuracy even when the system is put in entirely new context where it is interacting with new types of simulators. With a fixed step size, such adjustment would not be possible as the necessary uncertainty in implicit interpolation would be unavoidable.

A careful analysis of the inventor has revealed that the access to the step size to the function approximator is key in achieving better convergence properties. When comparing against neural ODEs, for example, the inclusion of non-linear response to a variable time step directly in the function approximator allows it to separate the dynamics of time-steps in the training data, which removes a lower bound on the prediction accuracy. This bound would have otherwise been imposed as it was trained to predict across a multitude of different time steps with a very limited ability to compensate for the different average rate-of-changes of the state across time steps. This problem can be exacerbated from feedback loops from the dynamic time step simulator. For example, the parameters of a neural ODE could influence the distribution of time steps chosen by the solver and this would, in turn, influence the target dynamic the neural ODE is trying to learn, as this target dynamic is dependent on the step-size distribution in a non-linear fashion that the neural ODE cannot fully compensate for. Such feedback loops may introduce significant instabilities that create divergence and prevent learning altogether. Using our invention, separation of the step size can benefit from the properties of the function approximator, i.e. true or approximate universal function properties under very mild assumptions, that can describe the dynamics as a function of step size to any desired accuracy. This is also what allows very large step sizes to be used, with significant computational gains, without hindering the necessary accuracy possible from small step sizes.

Additionally, variable step sizes allow more detailed modelling of moments of interest in the timeline that influence the accuracy more, while using fast low-resolution modelling over extended periods which are of little importance. This allows significantly reduced computational requirements with better computational scaling properties for processes that have sparse moments of interest.

### Simulation for Automated Design

Some aspects of the invention use simulations for automated design of vehicles, robots, analog or mixed electronic circuits, pharmaceutical treatments, and/or industrial processes. Such simulation is formulated by defining a relevant design optimization criteria. For example, an optimization criteria may encode the minimum required pipe size to allow sufficient flow in a sewage system throughout a simulated 100-year period may be identified by setting.

To accomplish this, a number of parameters describing the technical design are identified as the parameters to be influenced by the optimization. A design optimizer module can then be designed around the design objective and the parameter automatically optimized. Design optimizers, like the optimizer module, can utilize a variety of methods for optimization, for example gradient ascent, genetic algorithms, grid search.

### Control

Some aspect of the invention comprises control parameters. Such control parameters encode some aspect of the control produced by a control system controlling an industrial system. For example, they may encode current and/or future control signals to be given at minute intervals. In another example, they encode the weights of a neural network that will control an industrial system.

A control objective is an encoding of various technical and/or technical objectives to be achieved by the industrial process. The objective may, for example, be a scalar value that weights several such objectives according to some constants. For example, maximizing output, minimizing maintenance time and fuel costs can be various objectives that are balanced by a set of constants into a single control objective.

A control optimizer is a module that takes a simulator and an encoded control objective and produces optimized control parameters. The methods that can be used by the control optimizer are generally similar to those that can be used by the adaptation module.

The control optimizer can be used continuously to produce updated control and/or control plans for the industrial process. Alternatively, it can be used to train a control policy, for example encoded in a neural network or other decision process encoded by the control parameters, that can be separated from the optimizer after training. The advantages of this approach may, for example, be that production of an output by the policy can be computationally more efficient and/or using less memory than repeatedly performing optimization. Updating of the policy by the control optimizer can optionally be performed intermittently as new data becomes available.

Some aspects of the invention involve an industrial and/or technical process that uses such control signals produced directly or indirectly, i.e. through a policy, by the control optimizer. Such industrial processes also allow automated control with a higher complexity than possible by processes directly controlled by human operators.

### Example—Industrial Processes

An industrial system performing an industrial process herein refers to any fixed installation for conducting or assisting the production of a consumer or commercial goods or the provision of technical service. Examples of such includes pulp mills, mining operations. smelting plants, manufacturing plants, power plants, power transmission systems, ventilation systems, heating systems, cooling systems, pipelines, refineries, hydropower reservoir systems. chemical plants and water and sanitation systems.

The control of industrial processes usually takes places through a supervised control and data acquisition system (SCADA), although countless other options exist. For example, the control could be distributed on cloud services or managed in a peer-to-peer network. In some cases, such as networks of power plants or high-level plans for pulp mills, the control signals may be in part be human readable instructions for the control of technical systems communicated to human operators, who then follow them to control the details of the process.

Historical sensor data are usually available in SQL databases.

The control objectives relevant to industrial processes vary, but usually include one or more of the following: increased automation, risk reduction by avoiding certain states or values, better quality of the product, resource and energy usage, production rate, timing of production, fulfillment of plans, production mix, reduced maintenance needs and costs.

In addition to control systems, simulators are often used in the planning stage to design proper dimensioning of the industrial process and to automatically identify potential problems in proposed designs.

### Example—Electronic Circuit Design

Some embodiments of the invention are used to simulate an analog or mixed-signal circuits. The surrogates themselves will be in computer instructions that can easily be implemented in hardware. For example, function approximators such as already trained neural networks can very easily be translated to electronic components or automatically through various tools for electronic design. This can create surrogate electronic circuit designs with better accuracy, reduced size and/or material usage, faster calculation time and reduced energy usage.

Alternatively, the more efficient simulation allowable by the invention allow such circuits to be simulated and large sets of their parameters to be optimized automatically in order to achieve some objective of the electronic circuit. For example, a control objective can be for a sounds producing circuit to produce a particular sound or for a visual analysis circuit to perform automatic image recognition. Such technical control objectives may for example be dependent on some technical environment that also requires simulation by the invention. Such optimization also allows the circuit to better fulfill the technical control objective by allowing the optimization to proceed for longer and allows such optimization towards a control objective to take place with fewer computational resources.

### Example—Vehicles and/or Robots

A vehicle herein refers to any mobile machine that is able to transport a passenger or cargo. Cargo may be, for example instruments, munitions and/or equipment. Vehicles include road vehicles, aircraft, boats and so forth.

A robot herein is any mobile machine that is able to perform a complex set of tasks automatically.

These definition may of course overlap, as they are both complex mobile machinery, which usually require them to undertake a variety of tasks.

Some embodiments of the invention simulate, optimize and/or comprise a robots and vehicle controlled by the invention. Robots and vehicles face similar problems, as their mobility often requires interaction with an external environment of great spatial extent and complexity. Likewise, there is usually a great potential to improve the performance in such environments with a corresponding more complex control. This control often of sufficient complexity to exceeds the potential for human design, which is especially evident in tasks such as in self-driving cars or complex robotics.

Even in relatively simple designs, such as rockets required to fly in straight lines, complexity arises in various parameters controlling its physical aspects. Most notable are aerodynamics and fluid dynamics, which have a complex interaction with the vehicle and/or robots that is a function of its control. Advantages the invention provides here faster simulation, which can be turned into faster and/or more accurate simulation with a given computational resource. This brings advantages to the design such as better automated design optimizing various for example: aerodynamic resistance, improved suspension systems, better settings for PID controls, improved breaking, AC control, optimized fuel injection, optimized controllability, and various other improvements and optimizations that enhance the design. Advantages may for example be reduced drag, better vehicle speed, better controllability in terms of stability or efficiency.

Simulators are widespread and often mandatory step in the design of practically any type of vehicle today. Cars, trucks and aircrafts use industry-specific simulation tools in their design. Lately, the control of both has been increasingly complex by the inclusion of neural networks in their control systems, which often uses extensive training in simulator environments in order to produce synthetic data for the control systems to learn their behaviour. Advantages of more efficient simulation tools for control systems are reduced computation use and, for a given computation resource, benefits that may include, for example, training on larger synthetic data sets, which in turn may bring advantages such as, for example, increased vehicle safety, better fuel economy, reduced maintenance needs or higher allowable speed given a fixed safety level.

Robots tend to use models and simulations to derive desired control signals through reverse kinematics. Since exact solutions are difficult in most cases, function approximation is commonly applied in practice. These can form a control policy that produces the control inputs to actuators, given a description of the desired movement as input. Advantages here may be, for example, faster and/or more energy efficient movements and lower risk of failure due to a more fine-grained simulation possible with the often limited computation resource available.

This optimization may, for example, also be pushed a step further with reinforcement learning, where an actuator is trained directly towards a control objective in a simulator. Training purely from data generated off-policy is known to have severe limitations, as the distribution will differ from those generated from the desired policy. Complex parameterized policies, for example using function approximators, tend to be the preferred alternative. Simulators are in this case typically a necessary prerequisite for the design of the policy, where the specific advantages depend on the control objective used. The success of the policy is in most cases bounded by the time required to simulate training data, i.e. the control policy, the robot and/or vehicle and its environment.

### Example—Pulp Mill

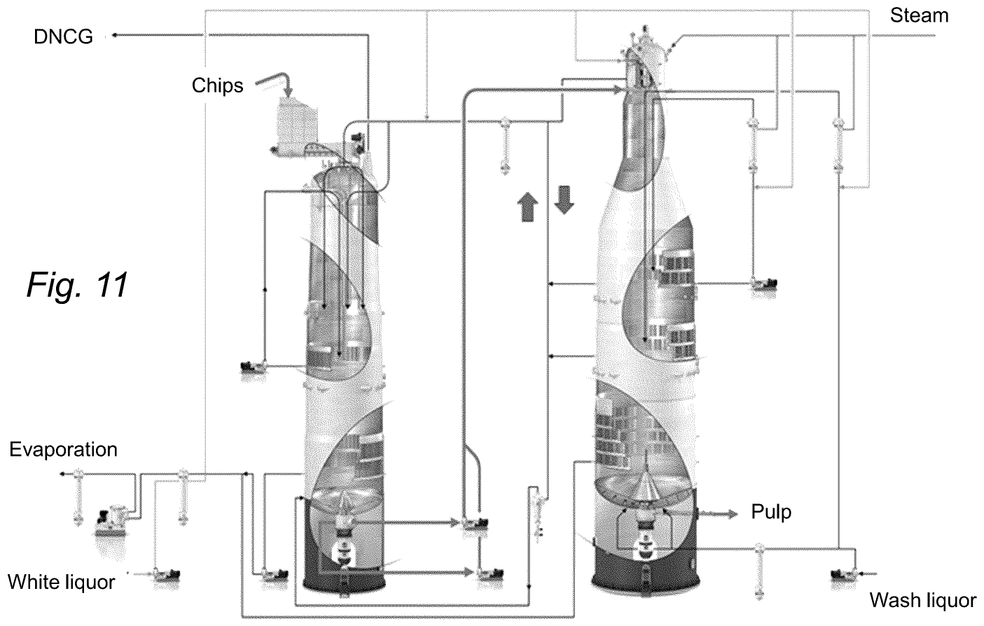

FIG. 11 is a schematic diagram illustrating an example of a pulp mill facility, or at least relevant parts thereof. By way of example, the configuration and/or operation of selected parts of the pulp mill may be simulated, and the simulation may be used for optimizing the pulp production in an example aspect of the invention. An example of a control objective may be stable production quality, where the control inputs are the heating and addition of chemicals.

In an example embodiment, historical data from an impregnation bin and digester in a pulp mill is collected for some time period. Sensor data and human control inputs are recorded in the historical data. Both processers are interconnected and controlled by a complex set of PID controllers and human control.

The internal state of the bin and digester are simulated as a series of compartment with temperature, density, the concentrations of a variety of chemicals and a variety of pulp substances as the model state. Additionally, the model state contains the rate of change of each of these variables. Each compartment is simulated as a neural network that takes the state of its connected compartments and the time step as an input. The PID controllers are simulated according to their known behavior as a series of differential equations.

Program instructions encoding a loss function is formulated as a simulator initializing a random historical moment from its historical state at that moment. Unmeasured internal states in the model are encoded as vector with a value for each minute, called the state parameters, which are considered part of the parameters of the model. The other model parameters are the parameters of the neural networks. The loss function simulates the process until a random following data point up to 20 minutes later and generates the mean absolute error when compared to the sensor values recorded in the data.

The computer instructions of the loss function are used to generate a gradient estimate with respect to the model parameters using reverse-mode automatic differentiation. The gradient is used in a stochastic gradient descent procedure in order to generate a set of model parameters that describes physical plant.

After training the human-controlled control signals are replaced by a neural network that takes current sensor values from the SCADA system and outputs a vector of control signals for controlling the process. In this new control model, the parameters of the neural network are sought in order to achieve a control objective. The control objective is to maintain a preset pulp quality while fulfilling a production quantity according to a given production plan, which can be sampled from historical data. The control model is initialized at random times in the historical points using the historical data and the state parameters and simulated to a random future data points up to 12 hours away. Step sizes in the simulation are set dynamically by starting with a large time step, comparing to a simulation with half that time step and reducing the time step if the difference in state between two simulations with different step sizes is above some absolute and relative threshold. The control objective outputs a scalar and the computer instructions encoding the control objective is used as input to a system that applies automatic differentiation to produce the gradient of the control objective with respect to control parameters. After a gradient-based procedure, the parameters encode a neural network control system trained to achieve the control objective. The neural network is encoded in a memory and delivered to the pulp mill for implementation as an automated control system inside the SCADA system that can replace the need for human control.

### Example—Wastewater System

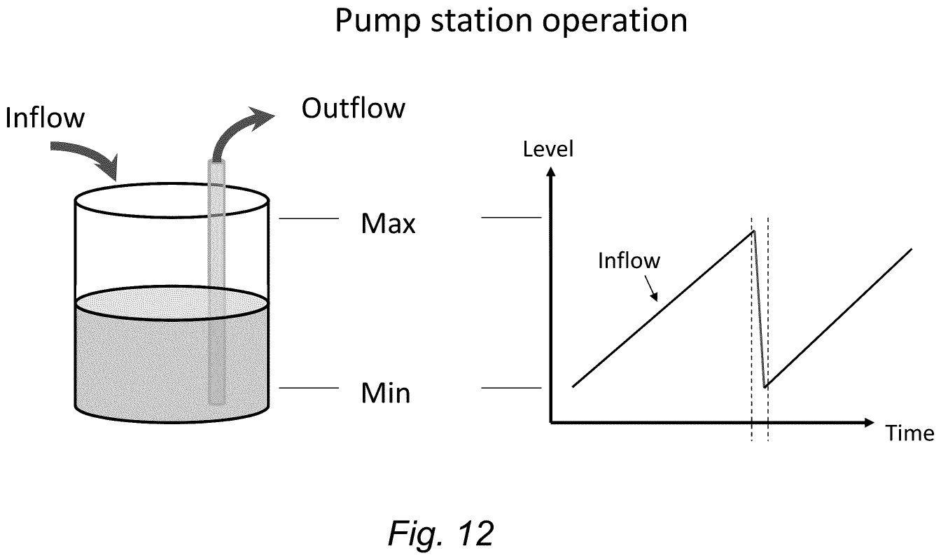

FIG. 12 is a schematic diagram illustrating an example of a model of pump station operation according to an embodiment.

The reservoir level of a reservoir is generally related to the inflow to the reservoir but also dependent on the outflow as determined by the operation of the corresponding pump station. For example, the reservoir level may increase due to a steady inflow, and then the pump station is activated during a certain time window, which results in a corresponding reduction of the reservoir level, followed by an increase of the reservoir level due to continued inflow.

An application example involves optimization of a pump system over time. Several interconnected reservoirs may be simulated with several external and internal flows. For example, energy efficiency and prevention of overflows of the reservoirs may be relevant desired control objectives.

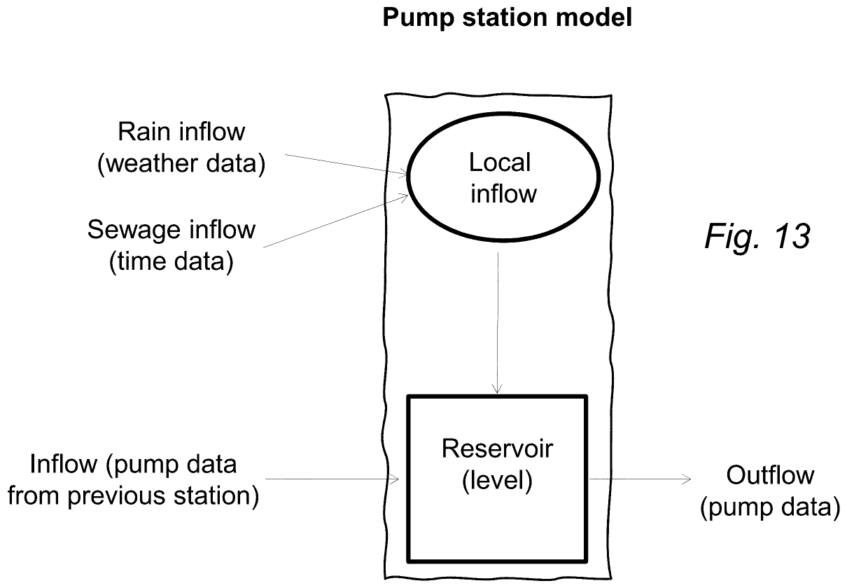

FIG. 13 is a schematic diagram illustrating an example of a pump or pumping station model.

For example, a simulation may use one or more of the following parameters, e.g. in order to predict a change in reservoir level:
two or more local inflows that are usually not directly measurable, e.g. precipitation and sewage, as functions of weather and time data, respectively;
inflow as a function of pumping data from a previous pumping station; and
outflow as a function of the stations' pumping measurements.

For example, it may be assumed that a particular part of the inflow into a reservoir associated with a certain pumping station is identical to the outflow from the previous pumping station over time. By way of example, any of the flows and the reservoir may each be simulated over time by a function approximator.

In a particular narrative of a pump-and-reservoir system such a wastewater system, an initial parameterized model of the pump and inflows, each as function of the variable(s) upon which it is dependent, may be stored in memory. The model may be trained on historic data using automatic and/or symbolic differentiation to generate an improved parameterized model. This model generates two sources of information on the inflow: the value created by the corresponding parameterized inflow model and the residual error of the model with respect to all other inflows.

In an example embodiment, all data from a municipal wastewater system is collected with their actual time stamps at randomly sampled intervals 2-5 minutes. A model is created with the following components: reservoirs giving height change as a function of the sum of flows into and from a reservoirs, pumping output giving negative flow as a function of current and/or past control signals (e.g. encoded as a vector with a value every minute in 120 min windows, with nearest measured data points being interpolated to provide these minute values) and/or reservoir heights of pumps pumping out of a reservoir, incoming water giving flow as a function of current and/or current pump control signals to pumps pumping into the reservoir, rainwater infiltration giving flow as a function of current and/or past rain and water usage giving flow as a function of time of the day and weekday. All the modules are simulated by function approximators and are given the time step as an additional input. The flows and reservoir levels in the model are connected logically according to the physical structure being simulated.

The loss function is calculated as follow: A current data point is sampled randomly from the data points in the data set. The system is then simulated to predict the reservoir levels of the next data points in the data set from the current data point in a single time step. Additionally, an alternative simulation until the next data points is performed by randomly sample a time between the two moments in time, i.e. the current and next data point, and the system is simulated from the current data point to the randomly sampled intermediate time to produce an intermediate state and a simulation is done from the intermediate time with the intermediate state to the time of the next data point. This produces two different simulation results corresponding to the next data points. For each of these, the difference between the simulated reservoir levels and the reservoir levels for that next data point is compared. The average mean square error across the predictions is calculated. The mean square error is the result of the loss function. Note that the loss function is stochastic and that the loss function we seek to minimize is the mean of the distribution encoded by the above stochastic loss function. Such implicitly encoded means of distributions are common in gradient descent procedures in statistical machine learning, e.g. using dropout or denoising autoencoders.

In this example, computer instructions creating a gradient estimate with respect to model parameters are generated by automated differentiation of the corresponding computer instructions encoding calculation of the loss function.

The gradient estimate is generated repeatedly and a stochastic gradient descent with momentum is applied using these gradient estimates in order to generate updated parameters. Effective hyperparameters of the momentum are chosen from experience or found through grid search. After repeatedly applying the parameter updates, the stored model parameters encode a model that achieves a lower mean loss and better model of the physical system.

After the model has been developed by identification of suitable parameters, optimization can begin. In this example, the optimization module is used in real-time to maintain a minute resolution pumping plan for controlling the pumps in the sewage system. The one minute plan may, for example, indicate an instruction to pump at full capacity for a set amount of time each minute and then turn off. An initial such plan can for example be developed through random or zero values, or identified through grid search. The control plan replaces the pump control data and/or pump control model used in the simulation. The simulation simulates twelve hours and uses fixed one-minute time steps. If the accuracy with one minute time steps is insufficient, the simulation model with new controls can be improved by training a new surrogate model so that the minute time steps imitate the simulation results of the original control simulation when simulated at smaller time intervals, i.e. by defining a loss function based on the difference between the original models smaller time steps and one minute time steps with the surrogate model. The parameters of the new surrogate model specifically adapted to one minute time steps in this specific scenario can be found by gradient descent.

The control objective in this example is defined as a negative penalty minimizing overflow in the reservoirs. The control objective can then be found by encoding the simulation of 12 hours of the control simulation and using the result to calculate the total overflow. To take into account stochastic nature of rain, an ensemble of models with different random seeds and stochastically generated input precipitation based on the latest rain forecast can be generated and the mean control objective calculated across all individual model runs.

Further in this example, automatic differentiation is used to calculate the derivatives of control objective with respect to the control parameters. In this particular example, this means identifying the gradient of the overflow with respect to each of the individual one minute average pumping instructions that encode the pumping plan. The gradient can be used by a control optimization module, e.g. a module that applies iterative updates based on gradient ascent to derive an improved pumping plan. If pumping values outside of the feasible range is suggested, they can be clamped to the highest possible value after updating the parameters in each iteration.

The pumping plan in this example can be calculated centrally by a computation node having access to real-time and historical data from a supervised control and data acquisition (SCADA) system. The pumping plan can then be transformed by the SCADA system into specific commands sent to the individual pumps in order to produce a pumping behaviour matching the pumping plan. Such specific commands can be tailored to each individual pump, depending on its particular abilities and interfaces for remote control through the SCADA system.

An autonomous or semi-autonomous wastewater system comprising pumps, pipes, reservoirs and the above control system can be constructed. In addition to the automation, it allows smaller dimension of reservoirs and pumps, as the better control can handle rare participation events more efficiently by planning the pumping well in advance and distribute the water storage evenly across several reservoirs.

### Example—Power Transmission

In another example, the power transmission of a power network is simulated. The predicted production from two different power plants, using gas and oil respectively, is modeled as a function of a control signal controlling the fuel consumption. The fixed losses and variable technical losses of the transmission lines, i.e. those that are a function of the current, are modelled by neural networks with the step size as an additional input. Each power plant is modelled by a set of differential equations in a differential equations solver, where the fuel injection is controlled according to its historical control inputs. The state of the power plant is modelled as fuel storage, temperature in the boiler and various momentums. The power consumption is given by a power usage plan per 15 minute sent by the industrial power plant to the power producer. Interpolation is used to produce consumption data for intermediate times from the values in the power usage plan.

The parameters of power production and transmission are the parameters of the neural networks as well as some key technical parameters used inside the differential equations.

The set of model parameters are adapted to the data through an evolutionary algorithm, where the negative of the mean absolute error of the simulated state and power output at each moment, as compared to historical data, is used as a fitness function.

After data adaptation, a control module is created. The control module is a neural network, which takes as inputs the requested power for the current and next 15 min intervals as well as the state of the power plant. The simulation is modified so that the control module replaces the historical control data as input to the fuel injection. A control objective is formulated as seeking the minimum cost for fuel, where a fuel price for each fuel type is inserted by the operator as constants, plus a term that penalizes differences from the desired power consumption. Evolutionary algorithms are applied to the control simulation in order to identify the neural network weights that result in the optimal policy encoded in the neural network in order to control the power production optimally according to the control objective.

The control parameters can be encoded into a physical medium, such as a flash memory, and copied into the SCADA system where they, together with other data from the SCADA system, will control the behaviour for a neural network that controls the fuel injection into the two power plants.

### Example—Control of a Rocket

In another example application, a rocket is simulated in order to construct a better control system of its flight through the atmosphere.

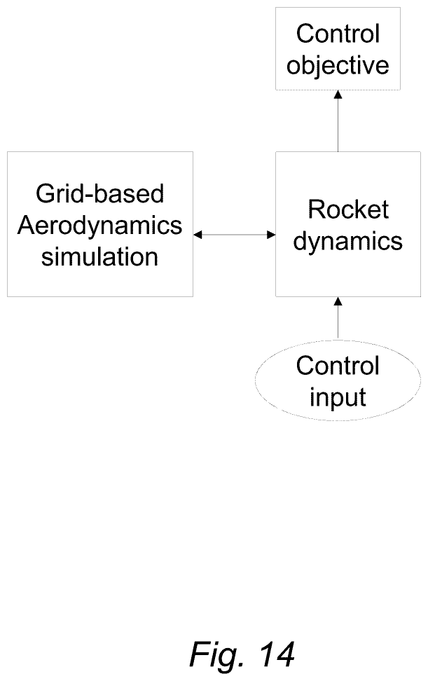

FIG. 14 is a schematic diagram illustrating an example of a modeling and simulation scheme used for a steerable rocket.

A model may be used for the setting the parameters of the control system. For example, the grid-based aerodynamics uses a finite-element simulation of the aerodynamics as it responds to the control surfaces of the rocket, which in turn influences the dynamics of the rocket.

For example, 3D grid-based simulation using the Navier-Stokes equations may be used to simulate the airflow on the control surfaces. This airflow model is connected to a set of differential equations that simulate the movements of the rocket and its control surfaces as a result of a control input given to the rocket.

After such an original model has been developed, a surrogate model is developed to imitate the effect of the simulation based on Navier-Stokes equations on the rocket dynamics in order to achieve faster simulation of this. A surrogate model based on recurrent neural networks are used to simulate the effect on the rocket dynamics based on the rocket state, the control input, the internal state of the recurrent neural network and the time step. A loss function is constructed as follows: The rocket is simulated twice: once according to the original model for a randomly chosen time period in some random interval and with time steps dynamically set by a predefined model tolerance; and once where the original Naves-Stokes model component has been replaced by the surrogate model and the same time period is being simulated in a single time step. The loss is calculated as the squared difference between the state of the rocket generated by using the surrogate model and the original is calculated.

In this example, automatic differentiation is applied on computer instructions encoding the loss function in order to output new computer instructions that encode calculation of the gradient with respect to surrogate model parameters. The gradient may be used to optimize the surrogate model parameters in a gradient descent procedure.

Once the surrogate model has been created in this example, it can be used to create a control system to optimize the control policy. This can be to identify the optimal parameters for a PID-control or to create a more complex non-linear control using a neural network.

After a control policy has been identified, the PID control or neural network can be implemented in an electronic circuit and installed inside a controllable rocket, thus resulting a rocket with optimized controls, higher speed, better turning efficiency, reduced drag, better safety and/or increased controllability.

### Example—Robotics

In another example, a robot is simulated using a set of differential equations describing its dynamics. The robot uses non-linear pneumatic actuators, which are modelled as neural networks using variable step sizes and the corresponding positions, momentum and velocities of connected components as inputs. The robot(s) may be modeled inside a 3D virtual environment, where various objects such as cubes and rods may sporadically interact with various components of the simulated robot. A preprogrammed control system controlling the actuators is also simulated.

Position data from various components of the physical robot when controlled by the same preprogrammed control system is collected through motion tracking into a historical data set. The positions of properties of physical objects interacting with it is also recorded and simulated. This historical data is used to improve the neural network model of the actuators by comparing their data to the predictions of the simulator. A squared loss error modified to ignore outliers through a set of data filters is used together with the simulator as a loss function.

In this example we assume that the simulator is not easily differentiable through automatic differentiation. Policy gradient algorithms such as REINFORCE are instead used to add Gaussian noise to the parameters values and thus minimize the loss function with respect to parameters.

After training the robot simulator in this example, an optimizer module is used to generate the optimal actuator control signals at millisecond level over some simulated time windows according to a set of control objective, e.g. catching a ball. The millisecond level control signal over the whole time window are initialized according to a manually encoded approximate behaviour for the robot. After training the optimal control signal, the optimizer module trains, through gradient descent, an isolated neural network with long short term memory nodes in order to create a policy that imitates the desired actuator control signals as a function of the information collected by a set of a sensor components. The encoded policy in the network parameters is then fine-tuned inside the full simulator through optimization with policy gradients using the control objective in order to produce the final neural network.

### Example—Drug Discovery Through Pharmacometrics

Pharmacometrics herein refers solely to a study of a drug therapy, i.e. pharmacokinetic and pharmacodynamic models. Such studies are today routine in drug discovery and for finding new applications of existing drugs. Medical simulations can vary from simple dynamical simulations of a few interacting substances without spatial reference, to extremely complex 3D environments requiring vast resources, such as BioDynaMo. Simulation speed, requiring reduced computation resources or providing greater simulation accuracy with a given computational resource, is typically essential to make satisfactory simulations that design provide sufficient drug safety, identify optimal dosage and schedule for administration of a substance to make it feasible as a candidate. Additionally, a larger amount of substances can be searched, which gives a better average therapeutic effect and/or lower side effects in the identified substance(s).

In a particular non-limiting example, an original pharmacometric model may be constructed using a set of new drugs that are modelled with known chemical and physiologically based models forming a set of differential equations. Once the model has been developed, a surrogate model is created based on a set of neural networks, each given some relevant part of the state of the model and the time step as an input.

The surrogate model may be trained to imitate the original model over some fixed or randomly sampled time steps, while the original model is solved with a preset relative and absolute tolerance inside the differential equations solver using. Both models are initialized with a random state inside some range of interest. The mean absolute difference between the models is used as a loss function. The loss for a sample is calculated and a tape describing the calculation is generated. The tape is then reversed in order to derive a program in reverse-mode automatic differentiation procedure that generates the gradients with respect to the neural network parameters of the surrogate model. The gradient may be used in a stochastic gradient descent procedure until the difference between the surrogate model and the original model reaches a preset threshold.

The surrogate model is then used to identify parameters of the medical intervention that is optimal considering a weighted set of safety and efficiency aspects that are calculated from the state of the simulation. The optimization uses genetic algorithms and outputs the improved scheduled dosages. After the optimization is complete, the desired therapeutic effects and known undesirable side effects are estimated from the simulation.

The above procedure may then be performed for a very large number of possible hypothetical substances whose properties have been identified through experiments and/or simulation. Alternatively, new substances can be identified dynamically and added to the list through genetic algorithms based on encodings of evaluated substances. The best performing substance is identified as a candidate treatment and used for further trials.

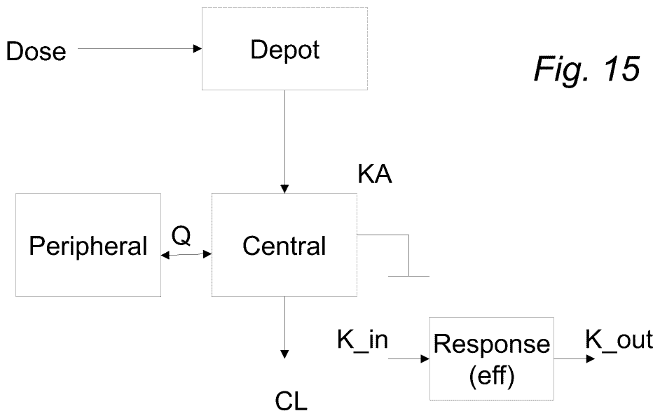

FIG. 15 is a schematic diagram illustrating an example of a pharmacokinetic model. In this example, the model is a two-compartment pharmacokinetic model with an indirect response pharmacodynamic model, freely adapted from “A Tutorial on RxODE: Simulating Differential Equation Pharmacometric Models in R”, Wang et al. CPT Pharmacometrics Syst. Pharmacol, 2016, which is incorporated herein by reference with respect to simulation of a pharmacometric model. The dynamics of one or more modules can be modelled by function approximators using data collected from patients. The scheduled doses can then be optimized to achieve the desired effects.

### Example—Analog and Mixed Electronics Simulation

In another example, a complex analog or mixed analog/digital electronic circuit is simulated. A surrogate model is trained to accelerate the simulation with larger step sizes and fewer calculations per step.

After training, the results surrogate based on one or more function approximators is converted to a design for a new analog, mixed or digital circuit performing the same calculations as the surrogate. The electric circuit based on the surrogate can now approximate the original electronic circuit, but potentially at a greatly reduced size and with lower electrical requirements. The time step in the surrogate encoding electronic circuit can also be modified in order to simulate the original circuit at a faster or slower rate.

It should be clear that the proposed technology may be applied, e.g. for improved adaptive modeling, simulation, evaluation and/or control of at least part of an industrial and/or technical system for at least one of industrial manufacturing, processing, and packaging, automotive and transportation, mining, pulping, infrastructure, energy and power applications and facilities, telecommunication, information technology, audio/video, life science, oil, gas, water treatment, sanitation and aerospace industry, but also for other applications such as drug discovery and so forth.

It will be appreciated that the methods and systems described herein can be combined and re-arranged in a variety of ways, and that the methods can be performed by one or more suitably programmed or configured digital signal processors and other known electronic circuits (e.g. discrete logic gates interconnected to perform a specialized function, or application-specific integrated circuits).

Many aspects of this invention are described in terms of sequences of actions that can be performed by, for example, elements of a programmable computer system.

The steps, functions, procedures and/or blocks described above may be implemented in hardware using any conventional technology, such as discrete circuit or integrated circuit technology, including both general-purpose electronic circuitry and application-specific circuitry.

Alternatively, at least some of the steps, functions, procedures and/or blocks described above may be implemented in software for execution by a suitable computer or processing device such as a microprocessor, Digital Signal Processor (DSP) and/or any suitable programmable logic device such as a Field Programmable Gate Array (FPGA) device and a Programmable Logic Controller (PLC) device.

It should also be understood that it may be possible to re-use the general processing capabilities of any device in which the invention is implemented. It may also be possible to re-use existing software, e.g. by reprogramming of the existing software or by adding new software components.

It is also possible to provide a solution based on a combination of hardware and software. The actual hardware-software partitioning can be decided by a system designer based on a number of factors including processing speed, cost of implementation and other requirements.

FIG. 16 is a schematic diagram illustrating an example of a computer-implementation 100 according to an embodiment. In this particular example, at least some of the steps, functions, procedures, modules and/or blocks described herein are implemented in a computer program 125; 135, which is loaded into the memory 120 for execution by processing circuitry including one or more processors 110. The processor(s) 110 and memory 120 are interconnected to each other to enable normal software execution. An optional input/output device 140 may also be interconnected to the processor(s) 110 and/or the memory 120 to enable input and/or output of relevant data such as input parameter(s) and/or resulting output parameter(s).

The term ‘processor’ should be interpreted in a general sense as any system or device capable of executing program code or computer program instructions to perform a particular processing, determining or computing task.

The processing circuitry including one or more processors 110 is thus configured to perform, when executing the computer program 125, well-defined processing tasks such as those described herein.

The processing circuitry does not have to be dedicated to only execute the above-described steps, functions, procedure and/or blocks, but may also execute other tasks.

Moreover, this invention can additionally be considered to be embodied entirely within any form of computer-readable storage medium having stored therein an appropriate set of instructions for use by or in connection with an instruction-execution system, apparatus, or device, such as a computer-based system, processor-containing system, or other system that can fetch instructions from a medium and execute the instructions.

The software may be realized as a computer program product, which is normally carried on a non-transitory computer-readable medium, for example a CD, DVD, USB memory, hard drive or any other conventional memory device. The software may thus be loaded into the operating memory of a computer or equivalent processing system for execution by a processor. The computer/processor does not have to be dedicated to only execute the above-described steps, functions, procedure and/or blocks, but may also execute other software tasks.

The flow diagram or diagrams presented herein may be regarded as a computer flow diagram or diagrams, when performed by one or more processors. A corresponding apparatus may be defined as a group of function modules, where each step performed by the processor corresponds to a function module. In this case, the function modules are implemented as a computer program running on the processor.

The computer program residing in memory may thus be organized as appropriate function modules configured to perform, when executed by the processor, at least part of the steps and/or tasks described herein.

Alternatively, it is possible to realize the module(s) predominantly by hardware modules, or alternatively by hardware, with suitable interconnections between relevant modules. Particular examples include one or more suitably configured digital signal processors and other known electronic circuits, e.g. discrete logic gates interconnected to perform a specialized function, and/or Application Specific Integrated Circuits (ASICs) as previously mentioned. Other examples of usable hardware include input/output (I/O) circuitry and/or circuitry for receiving and/or sending signals. The extent of software versus hardware is purely implementation selection.

It is becoming increasingly popular to provide computing services (hardware and/or software) where the resources are delivered as a service to remote locations over a network. By way of example, this means that functionality, as described herein, can be distributed or re-located to one or more separate physical nodes or servers. The functionality may be re-located or distributed to one or more jointly acting physical and/or virtual machines that can be positioned in separate physical node(s), i.e. in the so-called cloud. This is sometimes also referred to as cloud computing, which is a model for enabling ubiquitous on-demand network access to a pool of configurable computing resources such as networks, servers, storage, applications and general or customized services.

The embodiments described above are to be understood as a few illustrative examples of the present invention. It will be understood by those skilled in the art that various modifications, combinations and changes may be made to the embodiments without departing from the scope of the present invention. In particular, different part solutions in the different embodiments can be combined in other configurations, where technically possible.

1. A system (20; 30; 100) comprising:
one or more processors (110) and associated memory (120) configured for at least partly operating as a modular simulator having different simulator components, including:
a first type of simulator component including one or more function approximators, and
a second, different type of simulator component configured for interaction with said one or more function approximators;
wherein said modular simulator is configured to, by said one or more processors (110), operate as a variable time-step simulator based on a variable time-step to be simulated in each iteration and generate a simulation result; and
wherein said modular simulator is further configured to, by said one or more processors (110), simulate a dynamic physical process over time based on said first type of simulator component including one or more function approximators and said second, different type of simulator component both given an input based at least in part on said variable time-step to be simulated in each iteration.

2. The system of claim 1, wherein the interaction between said first type of simulator component including one or more function approximators and said second, different type of simulator component is such that both influence the operation of the other.

3. The system of claim 1, wherein said second, different type of simulator component includes one or more differential equation solvers operable with variable time-step.

4. The system of claim 1, wherein each function approximator is based at least in part on a variable time-step to be simulated in each iteration, and each function approximator is interacting with some simulated dynamic system that is not being simulated by that particular function approximator in the modular simulator.

5. A system (20; 30; 100) comprising:
one or more processors (110);
a memory (120) configured to store: parameters of one or more universal function approximators;
a variable time-step simulator configured to, by one or more processors (110), simulate a dynamic physical process over time based on said one or more function approximators given an input based at least in part on a variable time-step to be simulated in each iteration and generate a simulation result such that:
each function approximator is based at least in part on the variable time-step to be simulated in each iteration;
each function approximator is interacting with some simulated dynamic system that is not being simulated by that particular function approximator in the simulator.

6. The system of any of the claim 1, wherein said dynamic physical process is an industrial, technical and/or biomedical or medical process.

7. The system of claim 1, further comprising:
an adaptation module configured to, by the one or more processors (110), to update at least one model parameter of a parameterized model of the physical process based on an iterative optimization method.

8. The system of claim 7, further comprising:
a gradient estimator configured to, by the one or more processors (110), estimate a gradient on a loss function with respect to parameters of said one or more function approximators in order to generate a gradient estimate with respect to said function approximator parameters; and
wherein the adaptation module is configured to receive the gradient estimate and wherein the optimization method is a gradient-based optimization method.

9. The system of claim 8, wherein the memory is further configured to store computer instructions for the loss function such that the loss function can generate, by the one or more processors, an estimate of the difference between the simulation result and historical data.

10. The system of claim 8, wherein said gradient estimator is configured to apply reverse-mode automatic differentiation on the loss function in order to generate the gradient estimate.

11. The system of claim 1, wherein at least part of a system state not being updated directly by a parameterized model is simulated by a differential equation solver with variable time-step.

12. The system of claim 1, wherein the function and/or usage of said one or more function approximators is encoded in an acausal modelling language.

13. The system of claim 1, wherein said one or more function approximators include one or more Universal Function Approximators, UFA.

14. The system of claim 1, wherein said one or more function approximators include one or more neural networks.

15. The system of claim 1, further comprising a loss module configured to, by the one or more processors, retrieve a simulation result and historical sensor data from the physical process and generate a simulator loss.

16. The system of claim 1, further comprising:
a control optimizer configured to, by the one or more processors, generate a control plan based on the simulation and sensor data for a specified period and/or a control signal and directing said control plan and/or control signal for controlling an industrial and/or technical process.

17. The system of claim 1, further comprising a control optimizer configured to, by the one or more processors, generate and/or adjust parameters encoding the behaviour of a control system of an industrial and/or technical process.

18.-26. (canceled)

27. A computer-implemented method for performing a simulation of a dynamic physical process over time, said method comprising:
configuring and/or operating a modular simulator having different simulator components, including:
a first type of simulator component including one or more function approximators, and
a second, different type of simulator component configured for interaction with said one or more function approximators;
wherein said modular simulator is configured to operate as a variable time-step simulator based on a variable time-step to be simulated in each iteration and generate a simulation result; and
said modular simulator performing said simulation of a dynamic physical process over time based on said first type of simulator component including one or more function approximators and said second, different type of simulator component both given an input based at least in part on said variable time-step to be simulated in each iteration.

28. A method, performed by one or more processors, for evaluating and/or adapting at least one technical model related to a physical process defined as an industrial and/or technical process to be performed by an industrial and/or technical system, said method for evaluating and/or adapting at least one technical model comprising a computer-implemented method for performing a simulation of a dynamic physical process according to claim 27.

29. A method, performed by one or more processors, for enabling control of an industrial and/or technical system that is configured for performing a physical process defined as an industrial and/or technical process, said method for enabling control of an industrial and/or technical system comprising a method for evaluating and/or adapting at least one technical model related to a physical process according to claim 28.

30. (canceled)

31. (canceled)
